(19) United States
(12) Patent Application Publication
(10) Pub. No.: US 2026/0020333 A1
(43) Pub. Date: Jan. 15, 2026

(54) SEMICONDUCTOR DEVICE AND METHOD OF MANUFACTURING THE SAME

(71) Applicant: SAMSUNG ELECTRONICS CO., LTD., Suwon-si (KR)

(72) Inventor: JINCHAN YUN, Suwon-si (KR)

(73) Assignee: SAMSUNG ELECTRONICS CO., LTD., Suwon-si (KR)

(21) Appl. No.: 19/074,042

(22) Filed: Mar. 7, 2025

(30) Foreign Application Priority Data
Jul. 9, 2024 (KR) 10-2024-0090173

(51) Int. Cl. H10D 84/83; H10D 30/00; H10D 30/01; H10D 30/43; H10D 62/10; H10D 62/13; H10D 64/01; H10D 84/01

(52) U.S. Cl. CPC H10D 84/832; H10D 30/014; H10D 30/019; H10D 30/43; H10D 30/502; H10D 62/121; H10D 62/151; H10D 84/0133; H10D 84/0149; H10D 84/8312; H10D 84/83138; H10D 64/017

(57) ABSTRACT

A semiconductor device includes a substrate, a transistor stack on the substrate, a first source/drain structure on a first side of the transistor stack, and a second source/drain structure on a second side of the transistor stack, where the transistor stack includes a lower transistor on the substrate, the lower transistor including a lower channel layer and a lower gate structure surrounding the lower channel layer, an upper transistor on the lower transistor, the upper transistor including an upper channel layer and an upper gate structure surrounding the upper channel layer, and a first connecting layer between the lower gate structure and the upper gate structure, and the first source/drain structure and the second source/drain structure are connected via the first connecting layer.

### CROSS-REFERENCE TO RELATED APPLICATION(S)

This application is based on and claims priority to Korean Patent Application No. 10-2024-0090173, filed on Jul. 9, 2024, in the Korean Intellectual Property Office, the disclosure of which is incorporated herein by reference in its entirety.

### BACKGROUND

Example embodiments of the disclosure relate to a semiconductor device and a method of manufacturing the semiconductor device.

There is a growing demand for transistors of reduced size to improve the density of logic devices on an integrated circuit. Accordingly, semiconductor devices of a multi-stack structure in which transistors are formed respectively in a lower stack and an upper stack are under development to increase the density of the transistors in a limited space on a substrate.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a semiconductor device capable of improved performance and space efficiency and a method of manufacturing the semiconductor device.

Additional aspects will be set forth in part in the description which follows and, in part, will be apparent from the description, or may be learned by practice of the presented embodiments.

According to an aspect of an example embodiment, a semiconductor device may include a substrate, a transistor stack on the substrate, a first source/drain structure on a first side of the transistor stack, and a second source/drain structure on a second side of the transistor stack, where the transistor stack includes a lower transistor on the substrate, the lower transistor including a lower channel layer and a lower gate structure surrounding the lower channel layer, an upper transistor on the lower transistor, the upper transistor including an upper channel layer and an upper gate structure surrounding the upper channel layer, and a first connecting layer between the lower gate structure and the upper gate structure, and the first source/drain structure and the second source/drain structure are connected via the first connecting layer.

According to an aspect of an example embodiment, a semiconductor device may include a substrate, a plurality of transistor stacks on the substrate, and a plurality of source/drain structures respectively between the plurality of transistor stacks, where each transistor stack of the plurality of transistor stacks includes a lower transistor on the substrate, the lower transistor including a lower channel layer and a lower gate structure surrounding the lower channel layer, and an upper transistor on the lower transistor, the upper transistor including an upper channel layer and an upper gate structure surrounding the upper channel layer, where each source/drain structure of the plurality of source/drain structures includes a lower source/drain between lower transistors of respective transistor stacks and an upper source/drain between upper transistors of respective transistor stacks, where a first source/drain structure of the plurality of source/drain structures, a first transistor stack of the plurality of transistor stacks, a second source/drain structure of the plurality of source/drain structures, a second transistor stack of the plurality of transistor stacks, and a third source/drain structure of the plurality of source/drain structures are arranged in sequential order in a first direction, and the first source/drain structure and the third source/drain structure are connected via a first connecting layer in the first transistor stack, a second connecting layer in the second source/drain structure, a fourth connecting layer in the second transistor stack, and a fifth connecting layer in the third source/drain structure.

According to an aspect of an example embodiment, a method of manufacturing a semiconductor device may include forming a plurality of dummy gate structures surrounding a lower channel layer and an upper channel layer, forming a lower source/drain between lower channel layers spaced apart from each other and that are surrounded by at least one dummy gate structure of the plurality of dummy gate structures, forming an upper source/drain between upper channel layers spaced apart from each other and that are surrounded by at least one dummy gate structure of the plurality of dummy gate structures, and forming a connecting layer passing between a first lower channel layer among the lower channel layers that are surrounded by at least one dummy gate structure of the plurality of dummy gate structures and a first upper channel layer of the upper channel layers that are surrounded by at least one dummy gate structure of the plurality of dummy gate structures, where the lower source/drain and the upper source/drain spaced apart from the at least one first dummy gate structure are connected via the connecting layer.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a perspective view of a semiconductor device according to one or more embodiments;

FIG. 2A is a cross-sectional view of a semiconductor device, taken along a cutting line I-I′ of FIG. 1, according to one or more embodiments;

FIG. 2B is a cross-sectional view of a semiconductor device, taken along a cutting line J-J′ of FIG. 1, according to one or more embodiments;

FIG. 3 is a cross-sectional view of a semiconductor device, taken along the cutting line I-I′ of FIG. 1, according to one or more embodiments;

FIG. 4 is a cross-sectional view of a semiconductor device, taken along the cutting line I-I′ of FIG. 1, according to one or more embodiments;

FIG. 5 is a cross-sectional view of a semiconductor device, taken along the cutting line I-I′ of FIG. 1, according to one or more embodiments;

FIG. 6 is a diagram illustrating a semiconductor device according to one or more embodiments;

FIG. 7A is a cross-sectional view of a semiconductor device, taken along the cutting line I-I′ of FIG. 1, according to one or more embodiments;

FIG. 7B is a cross-sectional view of a semiconductor device, taken along the cutting line J-J′ of FIG. 1, according to one or more embodiments;

FIG. 8 is a perspective view of a semiconductor device according to one or more embodiments;

FIGS. 9 and 10 are cross-sectional views of a semiconductor device, taken along a cutting line K-K′ of FIG. 8, according to one or more embodiments;

FIG. 11 is a cross-sectional view of a semiconductor device, taken along the cutting line K-K′ of FIG. 8, according to one or more embodiments;

FIG. 12 is a cross-sectional view of a semiconductor device, taken along the cutting line K-K′ of FIG. 8, according to one or more embodiments;

FIG. 13 is a diagram illustrating a semiconductor device according to one or more embodiments;

FIG. 14 is a perspective view of a semiconductor device according to one or more embodiments;

FIGS. 15 and 16 are cross-sectional views of a semiconductor device, taken along a cutting line L-L′ of FIG. 14, according to one or more embodiments;

FIG. 17 is a diagram illustrating a semiconductor device according to one or more embodiments;

FIG. 18 is a perspective view of a semiconductor device according to one or more embodiments;

FIGS. 19 and 20 are cross-sectional views of a semiconductor device, taken along a cutting line N-N′ of FIG. 18, according to one or more embodiments;

FIG. 21 is a diagram illustrating a semiconductor device according to one or more embodiments;

FIG. 22 is a flowchart illustrating a method of manufacturing a semiconductor device according to one or more embodiments;

FIGS. 23 through 39B are diagrams illustrating a process of manufacturing a semiconductor device according to one or more embodiments; and

FIGS. 40 and 41 are circuit diagrams illustrating a circuit formed by a semiconductor device according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

The terminology used herein is for describing various examples only and is not to be used to limit the disclosure. The articles “a,” “an,” and “the” are intended to include the plural forms as well, unless the context clearly indicates otherwise. As used herein, the term “and/or” includes any one and any combination of any two or more of the associated listed items. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

Also, in the following description with reference to the accompanying drawings, identical components are given the same reference numerals regardless of signs in the drawings, and repeated descriptions thereof may be omitted.

Where a component is described as “connected,” “coupled,” or “bonded” to another component, it is to be understood that the component may be directly connected, coupled, or bonded to the other component, but that there may be another component intervening therebetween.

Also, components included in one embodiment, and components having common features, are described using the same designations in other embodiments. Unless otherwise indicated, the description of one embodiment is applicable to the other embodiments, and detailed and repeated descriptions thereof are omitted.

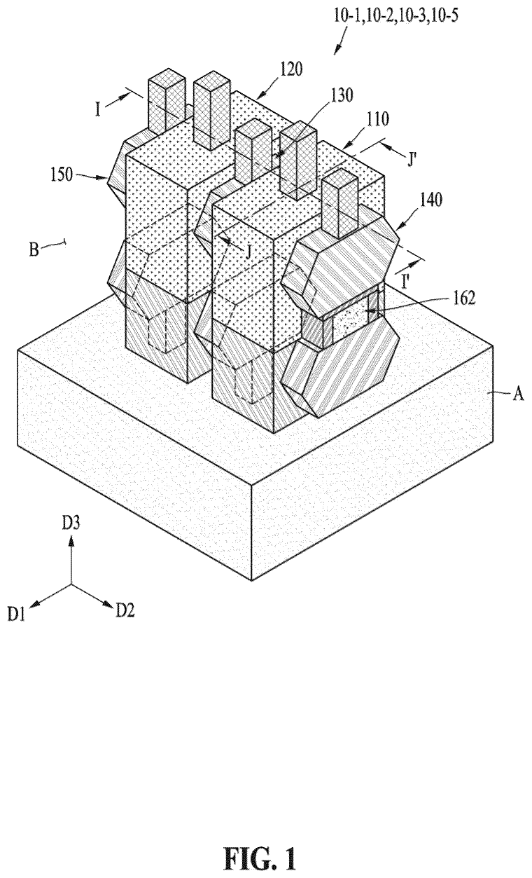

FIG. 1 is a perspective view of a semiconductor device according to one or more embodiments.

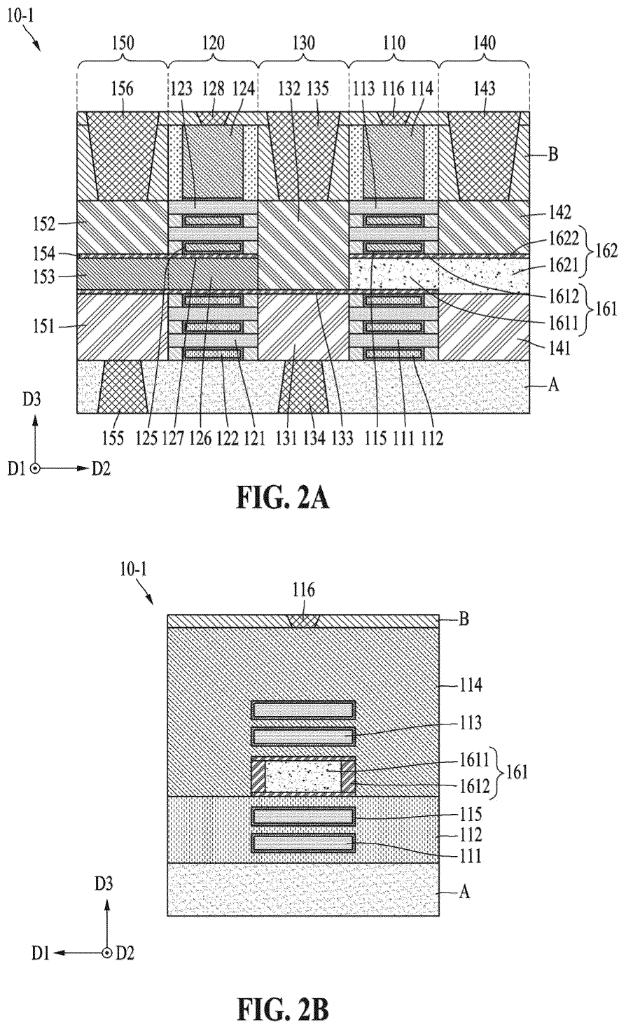

According to one or more embodiments, a semiconductor device (e.g., 10-1, 10-2, 10-3, and 10-5) may include a substrate A, at least one transistor stack (e.g., 110 and 120) formed on the substrate A, and at least one source/drain structure (e.g., 130, 140, and 150) disposed on one side or the other side of the at least one transistor stack. The semiconductor device (e.g., 10-1, 10-2, 10-3, and 10-5) may also include an interlayer dielectric (see B at FIG. 2, for example) that may fill between the at least one transistor stack (e.g., 110 and 120) and the at least one source/drain structure (e.g., 130, 140, and 150).

The substrate A may be a bulk substrate formed of a semiconductor material, such as a silicon (Si), silicon-germanium (SiGe), or silicon-on-insulator (SOI) substrate. Alternatively, the substrate A may be an insulating substrate including an insulating material. The insulating substrate may include, for example, but is not limited to, at least one of silicon oxide, silicon nitride, silicon oxynitride, and silicon carbide.

In the at least one transistor stack or the at least one source/drain structure, at least one connecting layer may be formed. In one or more embodiments, a second connecting layer 162 described later may be disposed between a second lower source/drain and a second upper source/drain of a second source/drain structure 140.

The transistor stacks 110 and 120 are shown as being aligned along a second direction D2 but are not limited thereto, and additional transistor stacks may be aligned along a first direction D1.

The first direction D1 and the second direction D2 may refer to directions that are parallel to a top surface of the substrate A and are perpendicular to each other. A third direction D3 may refer to a direction that is perpendicular to the first direction D1 and the second direction D2.

FIG. 2A is a cross-sectional view of a semiconductor device, taken along a cutting line I-I′ of FIG. 1, according to one or more embodiments. FIG. 2B is a cross-sectional view of a semiconductor device, taken along a cutting line J-J′ of FIG. 1, according to one or more embodiments.

Referring to FIGS. 2A and 2B, at least one transistor stack (e.g., 110 and 120) of a semiconductor device 10-1 may include a lower transistor formed on the substrate A and including at least one lower channel layer (e.g., 111 and 121) and a lower gate structure (e.g., 112 and 122) surrounding the at least one lower channel layer (e.g., 111 and 121). The at least one transistor stack (e.g., 110 and 120) may include an upper transistor formed on the lower transistor and including at least one upper channel layer (e.g., 113 and 123) and an upper gate structure (e.g., 114 and 124) surrounding the at least one upper channel layer (e.g., 113 and 123).

A first transistor stack 110 may include a first lower transistor and a first upper transistor. The first lower transistor may include two first lower channel layers 111 and a first lower gate structure 112 surrounding the two first lower channel layers 111. The first upper transistor may include two first upper channel layers 113 and a first upper gate structure 114 surrounding the two first upper channel layers 113. Although a first lower channel layer and a first upper channel layer are shown as the two first lower channel layers 111 and the two first upper channel layers 113, respectively, embodiments are not limited thereto. For example, the first lower channel layer and the first upper channel layer may each be formed as a single channel layer or as a plurality of channel layers including three or more channel layers.

The first lower transistor of the first transistor stack 110 may be a p-type metal-oxide-semiconductor (MOS) field-effect transistor (FET) (MOSFET) (PMOS). The first upper transistor of the first transistor stack 110 may be an n-type MOSFET (NMOS).

At both ends of a first lower channel layer 111 in the second direction D2, lower sources/drains described later may be formed, and the lower sources/drains may be connected via the first lower channel layer 111 that functions as a current flow channel for the first lower transistor.

At both ends of a first upper channel layer 113 in the second direction D2, upper sources/drains described later may be formed, and the upper sources/drains may be connected via the first upper channel layer 113 that functions as a current flow channel for the first upper transistor.

The first lower channel layer 111 or the first upper channel layer 113 may each be a nanosheet film that is aligned in the third direction D3 and includes a semiconductor material. The nanosheet film may include, for example, silicon (Si) or silicon-germanium (SiGe). The nanosheet film may be obtained through multiple processes including, but not limited to, photolithography and subtractive etch.

The first lower gate structure 112 or the first upper gate structure 114 may each be formed of a plurality of films including a work function metal film and a gate electrode film. The work function metal film may include titanium (Ti), tantalum (Ta), or a compound thereof, and the gate electrode film may include copper (Cu), aluminum (Al), tungsten (W), molybdenum (Mo), ruthenium (Ru), or a compound thereof. However, embodiments are not limited thereto.

The first lower gate structure 112 or the first upper gate structure 114 may be formed through atomic layer deposition (ALD), chemical vapor deposition (CVD), physical vapor deposition (PVD), plasma-enhanced CVD (PECVD), reactive-ion etching (RIE), chemical oxide removal (COR), or combinations thereof.

A top surface, bottom surface, or side surfaces of each of the first lower channel layers 111 and the first upper channel layers 113 relative to the first direction D1 and the third direction D3 may be covered by a first gate insulating layer 115. The first gate insulating layer 115 may be formed between the first lower channel layers 111 and the first lower gate structure 112. The first gate insulating layer 115 may be formed between the first upper channel layers 113 and the first upper gate structure 114. The first gate insulating layer 115 may not be formed on surfaces of the first lower channel layers 111 and the first upper channel layers 113 that contact source/drain structures described later.

The first gate insulating layer 115 may include, but is not limited to, an interface layer formed of silicon oxide or silicon oxynitride. The first gate insulating layer 115 may include a high dielectric layer formed of hafnium oxide, hafnium silicate, hafnium oxynitride, hafnium silicon oxynitride, or hafnium. The first gate insulating layer 115 may also include, but is not limited to, a high dielectric layer formed of aluminum oxide, lanthanum oxide, lanthanum aluminum oxide, zirconium oxide, zirconium silicate, zirconium oxynitride, zirconium silicon oxynitride, titanium oxide, barium strontium titanium oxide, barium titanium oxide, strontium titanium oxide, yttrium oxide, aluminum oxide, tantalum oxide, or lead scandium tantalum oxide.

The first transistor stack 110 may further include a first connecting layer 161. The first connecting layer 161 may be disposed between a first lower channel layer 111 disposed uppermost in the first lower gate structure 112 and a first upper channel layer 113 disposed lowermost in the first upper gate structure 114.

Although the first connecting layer 161 is shown as being surrounded by the first upper gate structure 114, embodiments are not limited thereto. Conversely, the first connecting layer 161 may be surrounded by the first lower gate structure 112.

The first connecting layer 161 may include a first connecting line 1611 and a first insulating pattern 1612. A top surface, bottom surface, or side surface of the first connecting line 1611 relative to the first direction D1 and the third direction D3 may be covered by the first insulating pattern 1612. Of surfaces of the first connecting line 1611, surfaces excluding a surface that contacts the second connecting layer 162 and a first upper source/drain 132 of a first source/drain structure 130 described later may be covered by the first insulating pattern 1612. The first insulating pattern 1612 may prevent direct contact between the first connecting line 1611 and the first upper gate structure 114 or the first lower gate structure 112.

Although it is shown that a thickness of the first insulating pattern 1612 covering the top and bottom surfaces of the first connecting line 1611 along the first direction D1 and the third direction D3 is less (or thinner) than a thickness of the first insulating pattern 1612 covering both side surfaces of the first connecting line 1611, embodiments are not limited thereto. Alternatively, the thickness of the first insulating pattern 1612 covering the top and bottom surfaces of the first connecting line 1611 may be greater (or thicker) than the thickness of the first insulating pattern 1612 covering both side surfaces of the first connecting line 1611. Alternatively, the thickness of the first insulating pattern 1612 covering the top and bottom surfaces of the first connecting line 1611 may be formed to be the same as the thickness of the first insulating pattern 1612 covering both side surfaces of the first connecting line 1611.

The first connecting line 1611 of the first connecting layer 161 may be formed of metal. Alternatively, the first connecting line 1611 may be formed of an electrically conductive material, such as, but not limited to, a conductive metallic material such as cobalt (Co), tungsten (W), ruthenium (Ru), or combinations thereof.

The first insulating pattern 1612 may be formed of, but is not limited to, silicon oxide (SiO), silicon nitride (SiN), and/or silicon oxynitride (SiON).

A first transistor contact 116 may be connected to the first transistor stack 110. The first transistor contact 116 may receive and transfer gate input signals from and to a gate structure or connect the gate structure to other circuit elements.

The first transistor contact 116 and transistor contacts described later may be formed of an electrically conductive material, such as, but not limited to, a conductive metallic material such as cobalt (Co), tungsten (W), ruthenium (Ru), or combinations thereof. The first transistor contact 116 and the transistor contacts described later may be formed through, for example, but not limited to, direct and/or wet etching such as RIE, and deposition such as CVD and PECVD.

The first transistor contact 116 is shown as connected to the first upper gate structure 114 but is not limited thereto. Alternatively, a first transistor contact may be connected to the first lower gate structure 112. Alternatively, a transistor contact may be connected to each of the first upper gate structure 114 and the first lower gate structure 112.

The preceding description of the configurations or components of the first transistor stack 110 may apply equally or similarly to corresponding configurations or components of transistor stacks described later. However, embodiments are not limited thereto.

A second transistor stack 120 may include a second lower transistor and a second upper transistor. The second lower transistor may include two second lower channel layers 121 and a second lower gate structure 122 surrounding the two second lower channel layers 121. The second upper transistor may include two second upper channel layers 123 and a second upper gate structure 124 surrounding the two second upper channel layers 123. Although a second lower channel layer and a second upper channel layer are shown as two second lower channel layers (e.g., the second lower channel layers 121) and two second upper channel layers (e.g., the second upper channel layers 123), respectively, embodiments are not limited thereto. Alternatively, the second lower channel layer and the second upper channel layer may each be formed as a single channel layer or a plurality of channel layers including three or more channel layers.

The second lower transistor of the second transistor stack 120 may be a PMOS transistor. The second upper transistor of the second transistor stack 120 may be an NMOS transistor.

A top surface, bottom surface, or side surfaces of each of the second lower channel layers 121 and the second upper channel layers 123 relative to the first direction D1 and the third direction D3 may be covered by a second gate insulating layer 125.

The second transistor stack 120 may further include a first middle insulating layer 126. The first middle insulating layer 126 may be disposed between a second lower channel layer 121 disposed uppermost in the second lower gate structure 122 and a second upper channel layer 123 disposed lowermost in the second upper gate structure 124.

The first middle insulating layer 126 and middle insulating layers described later may be formed of, for example, but are not limited to, silicon oxide (SiO), silicon nitride (SiN), and/or silicon oxynitride (SiON).

A top surface, bottom surface, or side surfaces of the first middle insulating layer 126 relative to the first direction D1 and the third direction D3 may be covered by an insulating pattern 127. The insulating pattern 127 may be formed of, but is not limited to, silicon oxide (SiO), silicon nitride (SiN), and/or silicon oxynitride (SiON).

A connecting line may also be disposed in the second transistor stack 120, as in the first transistor stack 110. In this case, the first middle insulating layer 126 may be removed from the second transistor stack 120, and the connecting line may be disposed in place of the first middle insulating layer 126 in a space where the first middle insulating layer 126 is removed. The connecting line may be formed of metal. Alternatively, the connecting line may be formed of an electrically conductive material, such as, but not limited to, a conductive metallic material such as cobalt (Co), tungsten (W), ruthenium (Ru), or combinations thereof.

To the second transistor stack 120, a second transistor contact 128 may be connected. The second transistor contact 128 may receive and transfer gate input signals from and to a gate structure or connect the gate structure to other circuit elements. Although the second transistor contact 128 is shown as connected to the second upper gate structure 124, embodiments are not limited thereto. Alternatively, a second transistor contact may also be connected to the second lower gate structure 122. Alternatively, a transistor contact may be connected to each of the second upper gate structure 124 and the second lower gate structure 122.

The first source/drain structure 130 may include a first lower source/drain 131 disposed on one side of the first lower gate structure 112 and a first upper source/drain 132 disposed on one side of the first upper gate structure 114. The first lower source/drain 131 may be disposed between the first lower gate structure 112 and the second lower gate structure 122. The first upper source/drain 132 may be disposed between the first upper gate structure 114 and the second upper gate structure 124.

The first lower source/drain 131 may be formed of silicon (Si) or silicon-germanium (SiGe) doped with p-type impurities such as boron and/or gallium. The first upper source/drain 132 may be formed of silicon (Si) and doped with n-type impurities such as phosphorus and/or arsenic.

A level of the first upper source/drain 132 may be higher than a level of a bottom surface of the first connecting layer 161 and the level of the first upper source/drain 132 is lower than a top surface of the first connecting layer 161. A height of the first upper source/drain 132 along the third direction D3 may be greater (or longer) than heights of a second upper source/drain 142 and a third upper source/drain 152, which will be described later, along the third direction D3.

The height of the first upper source/drain 132 along the third direction D3 perpendicular to the substrate A may be greater (or longer) than a height of the first lower source/drain 131 along the third direction D3 perpendicular to the substrate A.

This structure of the first upper source/drain 132 described above may allow at least a portion of a side of the first upper source/drain 132 to contact at least a portion of a side of the first connecting layer 161. A lower portion of the side of the first upper source/drain 132 may contact a side of the first connecting line 1611 of the first connecting layer 161. An upper portion of the side of the first upper source/drain 132 may contact a side of the first upper channel layer 113.

An insulating pattern 133 may be formed between the first lower source/drain 131 and the first upper source/drain 132. The insulating pattern 133 may separate the first lower source/drain 131 and the first upper source/drain 132 from each other.

A first lower source/drain contact 134 may be connected to the first lower source/drain 131. A first upper source/drain contact 135 may be connected to the first upper source/drain 132. Each source/drain contact may be formed of an electrically conductive material, such as, but not limited to, a conductive metallic material such as cobalt (Co), tungsten (W), ruthenium (Ru), or combinations thereof. Each source/drain contact may be formed through, but not limited to, direct and/or wet etching such as RIE, and deposition such as CVD and PECVD.

A source/drain structure may be obtained by epitaxial growth of the substrate A and/or a lower and/or upper channel layer. The source/drain structure may also include a material that forms the substrate A and/or the lower and/or upper channel layer.

The preceding description of the configurations or components of the first source/drain structure 130 may apply equally or similarly to corresponding configurations or components of source/drain structures described later. However, embodiments are not limited thereto.

The second source/drain structure 140 may include the second lower source/drain 141 disposed on the other side of the first lower gate structure 112 and the second upper source/drain 142 disposed on the other side of the first upper gate structure 114.

The second lower source/drain 141 may be formed of silicon (Si) or silicon-germanium (SiGe) doped with p-type impurities such as boron and/or gallium. The second upper source/drain 142 may be formed of silicon (Si) and doped with n-type impurities such as phosphorus and/or arsenic.

The second source/drain structure 140 may include the second connecting layer 162 disposed between the second lower source/drain 141 and the second upper source/drain 142. The second connecting layer 162 may be formed by extending from the first connecting layer 161.

The second connecting layer 162 may include a second connecting line 1621 and a second insulating pattern 1622. A top surface or side surfaces of the second connecting line 1621 relative to the first direction D1 and the third direction D3 may be covered by the second insulating pattern 1622. Of surfaces of the second connecting line 1621, surfaces excluding a surface that contacts the first connecting layer 161 and the second lower source/drain 141 of the second source/drain structure 140 may be covered by the second insulating pattern 1622. At least a portion of a top surface of the second lower source/drain 141 may contact at least a portion of a bottom surface of the second connecting layer 162. The bottom surface of the second connecting line 1621 may contact the second lower source/drain 141. The second insulating pattern 1622 may prevent contact between the second connecting line 1621 and the second upper source/drain 142.

The second connecting line 1621 of the second connecting layer 162 may be formed of metal. Alternatively, the second connecting line 1621 may be formed of an electrically conductive material, such as, but not limited to, a conductive metallic material such as cobalt (Co), tungsten (W), ruthenium (Ru), or combinations thereof.

A second upper source/drain contact 143 may be connected to the second upper source/drain 142. As will be described later, as the second lower source/drain 141 is electrically connected to the first upper source/drain 132 of the first source/drain structure 130, no separate source/drain contact may be connected to the second lower source/drain 141. However, embodiments are not limited thereto.

The structure of the first transistor stack 110, the first source/drain structure 130, and the second source/drain structure 140 described above may electrically connect the first source/drain structure 130 and the second source/drain structure 140, which are spaced apart from each other relative to the first transistor stack 110.

The first source/drain structure 130 and the second source/drain structure 140 may be electrically connected via the first connecting layer 161 and the second connecting layer 162. The first upper source/drain 132 of the first source/drain structure 130 and the second lower source/drain 141 of the second source/drain structure 140 may be electrically connected via the first connecting layer 161 and the second connecting layer 162.

The third source/drain structure 150 may include a third lower source/drain 151 disposed on one side of the second lower gate structure 122 and a third upper source/drain 152 disposed on one side of the second upper gate structure 124.

The third lower source/drain 151 may be formed of silicon (Si) or silicon-germanium (SiGe) doped with p-type impurities such as boron and/or gallium. The third upper source/drain 152 may be formed of silicon (Si) and doped with n-type impurities such as phosphorus and/or arsenic.

The third source/drain structure 150 may further include a second middle insulating layer 153. The second middle insulating layer 153 may be disposed between the third lower source/drain 151 and the third upper source/drain 152. A top surface, bottom surface, or side surfaces of the second middle insulating layer 153 relative to the first direction D1 and the third direction D3 may be covered by an insulating pattern 154.

A third lower source/drain contact 155 may be connected to the third lower source/drain 151. A third upper source/drain contact 156 may be connected to the third upper source/drain 152.

The semiconductor device 10-1 may include an interlayer dielectric B that fills between a transistor stack and a source/drain structure. The interlayer dielectric B may be formed of, but is not limited to, silicon oxide (SiO), silicon nitride (SiN), and/or silicon oxynitride (SiON).

The semiconductor device 10-1 may include a power line and a signal line in addition to the configurations or components described above.

Hereinafter, description of aspects described above, which may be equally applicable hereto, may be omitted, and example semiconductor devices according to one or more will be described with differences therebetween.

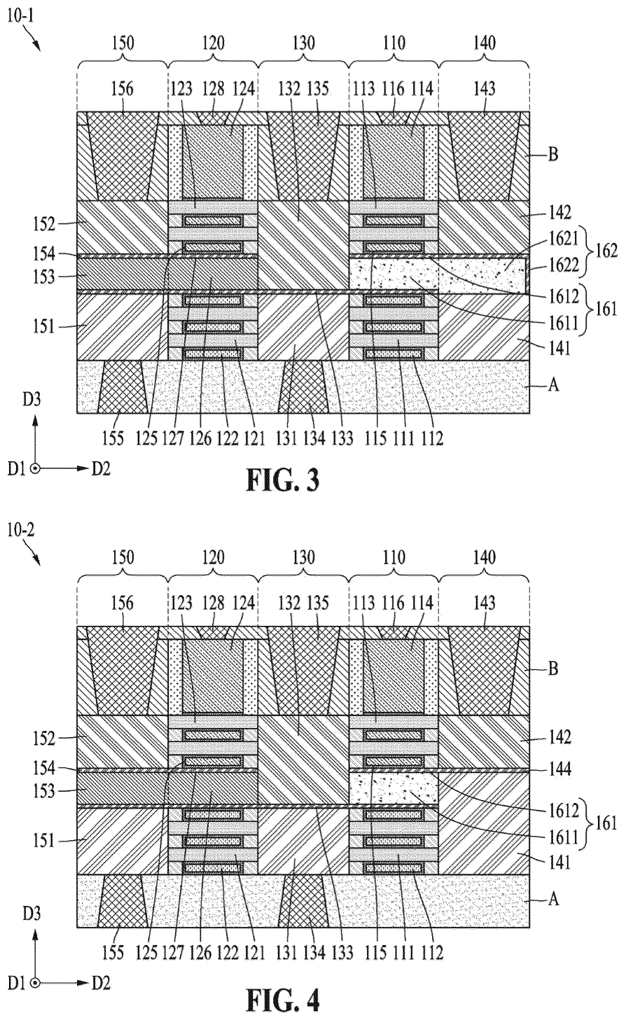

FIG. 3 is a cross-sectional view of a semiconductor device, taken along the cutting line I-I′ of FIG. 1, according to one or more embodiments.

Referring to FIG. 3, the second insulating pattern 1622 may further extend to cover one side of the second connecting line 1621 relative to the second direction D2 and the third direction D3. The second insulating pattern 1622 may cover one side of the second connecting line 1621 formed at a position opposite the other side of the second connecting line 1621 that contacts the first connecting line 1611.

FIG. 4 is a cross-sectional view of a semiconductor device, taken along the cutting line I-I′ of FIG. 1, according to one or more embodiments.

Referring to FIG. 4, a second source/drain structure 140 of a semiconductor device 10-2 may not include a second connecting layer 162 disposed between a second lower source/drain 141 and a second upper source/drain 142.

The second source/drain structure 140 may include the second lower source/drain 141 disposed on the other side of a first lower gate structure 112 and the second upper source/drain 142 disposed on the other side of a first upper gate structure 114.

The second lower source/drain 141 may be formed of silicon (Si) or silicon-germanium (SiGe) doped with p-type impurities such as boron and/or gallium. The second upper source/drain 142 may be formed of silicon (Si) and doped with n-type impurities such as phosphorus and/or arsenic.

A level of the second lower source/drain 141 may be higher than a level of a bottom surface of a first connecting layer 161 and the level of the second lower source/drain 141 may be lower than a level of a top surface of a first connecting layer 161. A height of the second lower source/drain 141 along the third direction D3 may be greater (or longer) than heights of a first lower source/drain 131 and a third lower source/drain 151 along the third direction D3.

The height of the second lower source/drain 141 along the third direction D3 perpendicular to the substrate A may be greater (or longer) than a height of the second upper source/drain 142 along the third direction D3 perpendicular to the substrate A.

This structure of the second lower source/drain 141 described above may allow at least a portion of a side of the second lower source/drain 141 to contact at least a portion of a side of the first connecting layer 161. An upper portion of the side of the second lower source/drain 141 may contact a side of a first connecting line 1611 of the first connecting layer 161. A lower portion of the side of the second lower source/drain 141 may contact a side of a first lower channel layer 111.

The second source/drain structure 140 may further include an insulating pattern 144 disposed between the second lower source/drain 141 and the second upper source/drain 142. The insulating pattern 144 may separate the second lower source/drain 141 and the second upper source/drain 142 from each other.

This structure may use only the first connecting layer 161 to directly connect a first upper source/drain 132 and the second lower source/drain 141.

A second upper source/drain contact 143 may be connected to the second upper source/drain 142. As the second lower source/drain 141 is electrically connected to the first upper source/drain 132 of the first source/drain structure 130, no separate source/drain contact may be connected to the second lower source/drain 141. However, embodiments are not limited thereto.

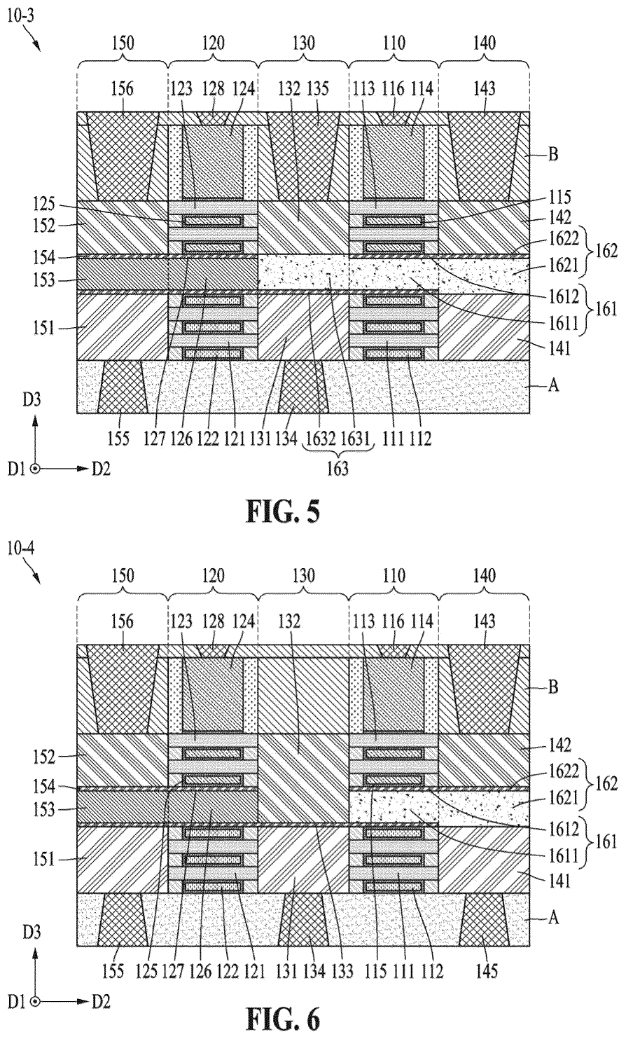

FIG. 5 is a cross-sectional view of a semiconductor device, taken along the cutting line I-I′ of FIG. 1, according to one or more embodiments.

Referring to FIG. 5, a first source/drain structure 130 of a semiconductor device 10-3 may include a third connecting layer 163 disposed between a first lower source/drain 131 and a first upper source/drain 132. The third connecting layer 163 may be formed by extending from a first connecting layer 161.

The third connecting layer 163 may include a third connecting line 1631 and a third insulating pattern 1632. A bottom or side surface of the third connecting line 1631 relative to the first direction D1 and the third direction D3 may be covered by the third insulating pattern 1632. Of surfaces of the third connecting line 1631, surfaces excluding a surface that contacts the first connecting layer 161 and the first upper source/drain 132 of a first source/drain structure 130 may be covered by the third insulating pattern 1632. At least a portion of a bottom surface of the first upper source/drain 132 may contact at least a portion of a top surface of the third connecting layer 163. A top surface of the third connecting line 1631 may contact the first upper source/drain 132. The third insulating pattern 1632 may prevent contact between the third connecting line 1631 and the first lower source/drain 131. At least a portion of a top surface of a second lower source/drain 141 may contact at least a portion of a bottom surface of a second connecting layer 162. The first upper source/drain 132 and the second lower source/drain 141 may be electrically connected via the first connecting layer 161, the second connecting layer 162, and the third connecting layer 163.

The third connecting line 1631 of the third connecting layer 163 may be formed of metal. Alternatively, the third connecting line 1631 may be formed of an electrically conductive material, such as, but not limited to, a conductive metallic material such as cobalt (Co), tungsten (W), ruthenium (Ru), or combinations thereof.

FIG. 6 is a diagram illustrating a semiconductor device according to one or more embodiments.

Referring to FIG. 6, a separate source/drain contact may not be connected to a first upper source/drain 132 of a semiconductor device 10-4. Instead, a second lower source/drain contact 145 may be connected to a second lower source/drain 141 that is electrically connected to the first upper source/drain 132. The second lower source/drain contact 145 may be formed of an electrically conductive material, such as, but not limited to, a conductive metallic material such as cobalt (Co), tungsten (W), ruthenium (Ru), or combinations thereof.

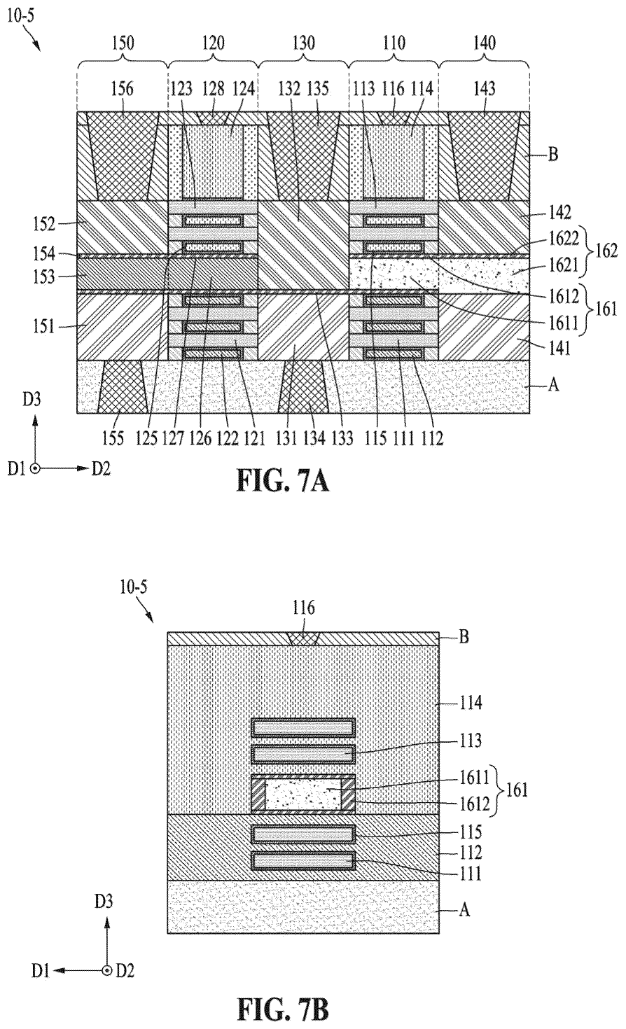

FIG. 7A is a cross-sectional view of a semiconductor device, taken along the cutting line I-I′ of FIG. 1, according to one or more embodiments. FIG. 7B is a cross-sectional view of a semiconductor device, taken along the cutting line J-J′ of FIG. 1, according to one or more embodiments.

In the semiconductor device 10-5, lower transistors of a first transistor stack 110 and a second transistor stack 120 may be NMOS transistors. Upper transistors of the first transistor stack 110 and the second transistor stack 120 may be PMOS transistors. Lower sources/drains 131, 141, and 151 of a first source/drain structure 130, a second source/drain structure 140, and a third source/drain structure 150 may be formed of silicon (Si) and doped with n-type impurities such as phosphorus and/or arsenic. Upper sources/drains 132, 142, and 152 of the first source/drain structure 130, the second source/drain structure 140, and the third source/drain structure 150 may be formed of silicon (Si) or silicon-germanium (SiGe) doped with p-type impurities such as boron and/or gallium.

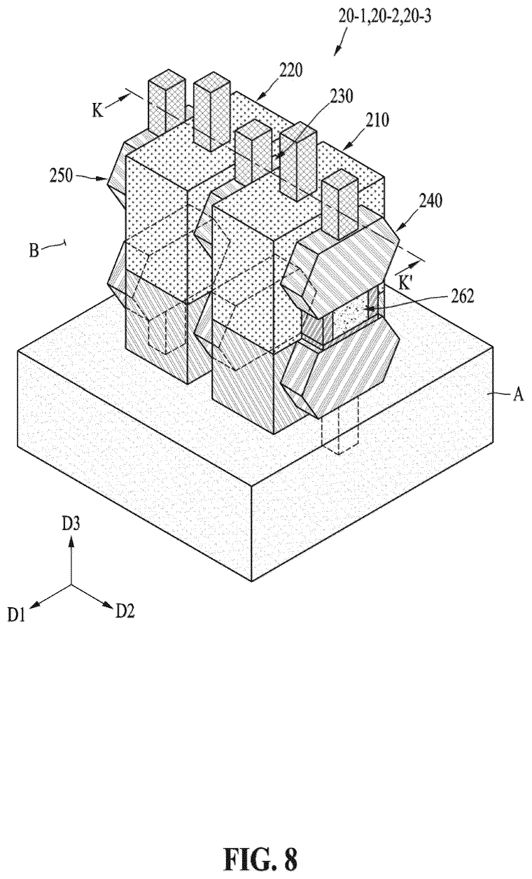

FIG. 8 is a perspective view of a semiconductor device according to one or more embodiments.

Referring to FIG. 8, a semiconductor device (e.g., 20-1, 20-2, and 20-3) may include a substrate A, at least one transistor stack (e.g., 210 and 220) formed on the substrate A, and at least one source/drain structure (230, 240, and 250) disposed on one side or the other side of the at least one transistor stack. The semiconductor device (e.g., 20-1, 20-2, and 20-3) may include an interlayer dielectric B that may fill between the at least one transistor stack (e.g., 210 and 220) and the at least one source/drain structure (230, 240, and 250).

At least one connecting layer may be formed in the at least one transistor stack or the at least one source/drain structure. For example, a second connecting layer 262 described later may be disposed between a second lower source/drain and a second upper source/drain of a second source/drain structure 240.

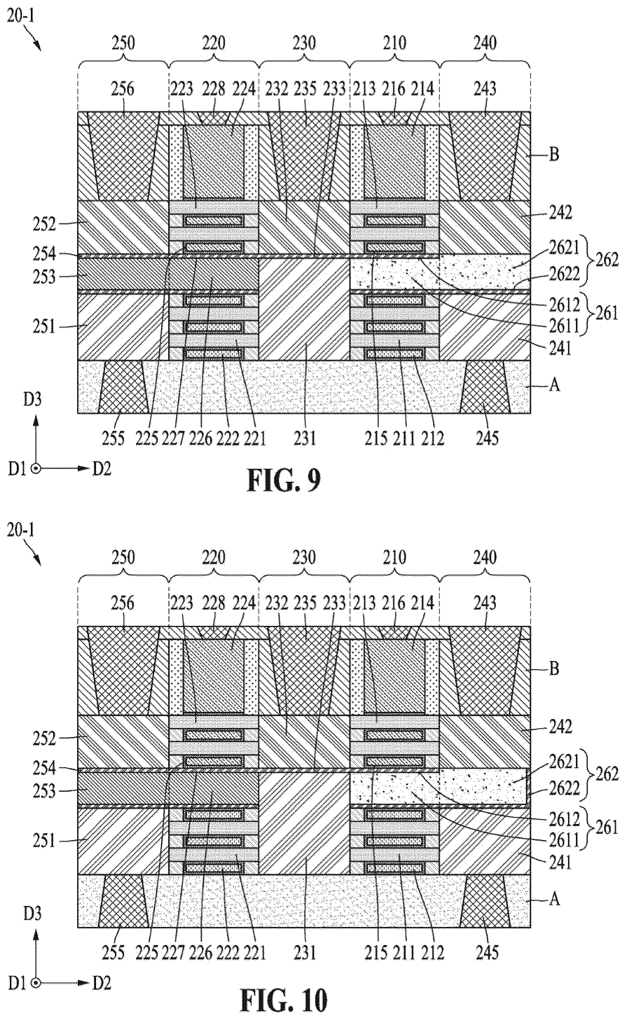

FIGS. 9 and 10 are cross-sectional views of a semiconductor device, taken along a cutting line K-K′ of FIG. 8, according to one or more embodiments.

Referring to FIG. 9, a first transistor stack 210 of a semiconductor device 20-1 may include a first lower transistor and a first upper transistor. The first lower transistor may include two first lower channel layers 211 and a first lower gate structure 212 surrounding the two first lower channel layers 211. The first upper transistor may include two first upper channel layers 213 and a first upper gate structure 214 surrounding the two first upper channel layers 213. Although a first lower channel layer and a first upper channel layer are each shown as two channel layers (e.g., the first lower channel layers 211 and the first upper channel layers 213), embodiments are not limited thereto. The first lower channel layer and the first upper channel layer may each be formed as a single channel layer or as a plurality of channel layers including three or more channel layers.

The first lower transistor of the first transistor stack 210 may be a PMOS transistor. The first upper transistor of the first transistor stack 210 may be an NMOS transistor. However, embodiments are not limited thereto.

A top surface, bottom surface, or side surfaces of each of the first lower channel layers 211 and the first upper channel layers 213 relative to the first direction D1 and the third direction D3 may be covered by a first gate insulating layer 215. The first gate insulating layer 215 may be formed between the first lower channel layers 211 and the first lower gate structure 212. The first gate insulating layer 215 may be formed between the first upper channel layers 213 and the first upper gate structure 214. No first gate insulating layer (e.g., 215) may be formed on surfaces of the first lower channel layers 211 and the first upper channel layers 213 that contact source/drain structures described later.

The first transistor stack 210 may further include a first connecting layer 261. The first connecting layer 261 may be disposed between a first lower channel layer 211 disposed uppermost in the first lower gate structure 212 and a first upper channel layer 213 disposed lowermost in the first upper gate structure 214. The first connecting layer 161 may be surrounded by the first upper gate structure 214 or the first lower gate structure 212.

The first connecting layer 261 may include a first connecting line 2611 and a first insulating pattern 2612. A top surface, bottom surface, or side surfaces of the first connecting line 2611 relative to the first direction D1 and the third direction D3 may be covered by the first insulating pattern 2612. Of surfaces of the first connecting line 2611, surfaces excluding a surface that contacts a second connecting layer 262 and a first lower source/drain 231 of a first source/drain structure 230 described later may be covered by the first insulating pattern 2612. The first insulating pattern 2612 may prevent direct contact between the first connecting line 2611 and the first upper gate structure 214 or the first lower gate structure 212.

A first transistor contact 216 may be connected to the first transistor stack 210. Although the first transistor contact 216 is shown as connected to the first upper gate structure 214, embodiments are not limited thereto. A first transistor contact may also be connected to the first lower gate structure 212. Alternatively, a transistor contact may be connected to each of the first upper gate structure 214 and the first lower gate structure 212.

A second transistor stack 220 may include a second lower transistor and a second upper transistor. The second lower transistor may include two second lower channel layers 221 and a second lower gate structure 222 surrounding the two second lower channel layers 221. The second upper transistor may include two second upper channel layers 223 and a second upper gate structure 224 surrounding the two second upper channel layers 223. Although a second lower channel layer and a second upper channel layer are shown as two channel layers (e.g., the second lower channel layers 221 and the second upper channel layers 223), embodiments are not limited thereto. The second lower channel layer and the second upper channel layer may each be formed as a single channel layer or as a plurality of channel layers including three or more channel layers.

The second lower transistor of the second transistor stack 220 may be a PMOS transistor. The second upper transistor of the second transistor stack 220 may be an NMOS transistor. However, embodiments are not limited thereto.

A top, bottom, or side surfaces of each of the second lower channel layers 221 and the second upper channel layers 223 relative to the first direction D1 and the third direction D3 may be covered by a second gate insulating layer 225.

The second transistor stack 220 may further include a first middle insulating layer 226. The first middle insulating layer 226 may be disposed between a second lower channel layer 221 disposed uppermost in the second lower gate structure 222 and a second upper channel layer 223 disposed lowermost in the second upper gate structure 224. A top, bottom, or side surfaces of the first middle insulating layer 226 relative to the first direction D1 and the third direction D3 may be covered by an insulating pattern 227.

A connecting line may be disposed for the second transistor stack 220, as in the first transistor stack 210. In this case, the first middle insulating layer 226 may be removed from the second transistor stack 220, and the connecting line may be disposed in place of the first middle insulating layer 226 in a space where the first middle insulating layer 226 is removed.

To the second transistor stack 220, a second transistor contact 228 may be connected. Although the second transistor contact 228 is shown as connected to the second upper gate structure 224, embodiments are not limited thereto. A second transistor contact may also be connected to the second lower gate structure 222. Alternatively, a transistor contact may be connected to each of the second upper gate structure 224 and the second lower gate structure 222.

A first source/drain structure 230 may include a first lower source/drain 231 disposed on one side of the first lower gate structure 212 and a first upper source/drain 232 disposed on one side of the first upper gate structure 214. The first lower source/drain 231 may be disposed between the first lower gate structure 212 and the second lower gate structure 222. The first upper source/drain 232 may be disposed between the first upper gate structure 214 and the second upper gate structure 224.

The first lower source/drain 231 may be formed of silicon (Si) or silicon-germanium (SiGe) doped with p-type impurities such as boron and/or gallium. The first upper source/drain 232 may be formed of silicon (Si) and doped with n-type impurities such as phosphorus and/or arsenic. However, embodiments are not limited thereto.

A level of the first lower source/drain 231 may be higher than a level of a bottom surface of the first connecting layer 261 and the level of the first lower source/drain 231 may be lower than a level of a top surface of the first connecting layer 261. A height of the first lower source/drain 231 along the third direction D3 may be greater (or longer) than heights of a second lower source/drain 241 and a third lower source/drain 251 along the third direction D3.

The height of the first lower source/drain 231 along the third direction D3 perpendicular to the substrate A may be greater (or longer) than a height of the first upper source/drain 232 along the third direction D3 perpendicular to the substrate A.

This structure of the first lower source/drain 231 described above may allow at least a portion of a side of the first lower source/drain 231 to contact at least a portion of a side of the first connecting layer 261. An upper portion of the side of the first lower source/drain 231 may contact a side of the first connecting line 2611 of the first connecting layer 261. A lower portion of the side of the first lower source/drain 231 may contact a side of a first lower channel layer 211.

An insulating pattern 233 may be formed between the first lower source/drain 231 and the first upper source/drain 232. The insulating pattern 233 may separate the first lower source/drain 231 and the first upper source/drain 232 from each other.

A first upper source/drain contact 235 may be connected to the first upper source/drain 232. As will be described later, as the first lower source/drain 231 is electrically connected to a second upper source/drain 242 of a second source/drain structure 240, no separate source/drain contact may be connected to the first lower source/drain 231. However, embodiments are not limited thereto.

The second source/drain structure 240 may include a second lower source/drain 241 disposed on the other side of the first lower gate structure 212 and the second upper source/drain 242 disposed on the other side of the first upper gate structure 214.

The second lower source/drain 241 may be formed of silicon (Si) or silicon-germanium (SiGe) doped with p-type impurities such as boron and/or gallium. The second upper source/drain 242 may be formed of silicon (Si) and doped with n-type impurities such as phosphorus and/or arsenic. However, embodiments are not limited thereto.

The second source/drain structure 240 may include the second connecting layer 262 disposed between the second lower source/drain 241 and the second upper source/drain 242. The second connecting layer 262 may be formed by extending from the first connecting layer 261.

The second connecting layer 262 may include a second connecting line 2621 and a second insulating pattern 2622. A bottom or side surface of the second connecting line 2621 relative to the first direction D1 and the third direction D3 may be covered by the second insulating pattern 2622. Of surfaces of the second connecting line 2621, surfaces excluding a surface that contacts the first connecting layer 261 and the second upper source/drain 242 of the second source/drain structure 240 may be covered by the second insulating pattern 2622. At least a portion of a bottom surface of the second upper source/drain 242 may contact at least a portion of a top surface of the second connecting layer 262. A top surface of the second connecting line 2621 may contact the second upper source/drain 242. The second insulating pattern 2622 may prevent contact between the second connecting line 2621 and the second lower source/drain 241.

The second connecting line 2621 of the second connecting layer 262 may be formed of metal. Alternatively, the second connecting line 2621 may be formed of an electrically conductive material, such as, but not limited to, a conductive metallic material such as cobalt (Co), tungsten (W), ruthenium (Ru), or combinations thereof.

A second lower source/drain contact 245 may be connected to the second lower source/drain 241. A second upper source/drain contact 243 may be connected to the second upper source/drain 242.

The structure of the first transistor stack 210, the first source/drain structure 230, and the second source/drain structure 240 described above may allow the first source/drain structure 230 and the second source/drain structure 240, which are spaced apart from each other relative to the first transistor stack 210, to be electrically connected.

The first source/drain structure 230 and the second source/drain structure 240 may be electrically connected via the first connecting layer 261 and the second connecting layer 262. The first connecting layer 261 and the second connecting layer 262 may electrically connect the first lower source/drain 231 of the first source/drain structure 230 and the second upper source/drain 242 of the second source/drain structure 240.

A third source/drain structure 250 may include a third lower source/drain 251 disposed on one side of the second lower gate structure 222 and a third upper source/drain 252 disposed on one side of the second upper gate structure 224.

The third lower source/drain 251 may be formed of silicon (Si) or silicon-germanium (SiGe) doped with p-type impurities such as boron and/or gallium. The third upper source/drain 252 may be formed of silicon (Si) and doped with n-type impurities such as phosphorus and/or arsenic. However, embodiments are not limited thereto.

The third source/drain structure 250 may further include a second middle insulating layer 253. The second middle insulating layer 253 may be disposed between the third lower source/drain 251 and the third upper source/drain 252. A top, bottom, or side surfaces of the second middle insulating layer 253 relative to the first direction D1 and the third direction D3 may be covered by an insulating pattern 254.

A third lower source/drain contact 255 may be connected to the third lower source/drain 251. A third upper source/drain contact 256 may be connected to the third upper source/drain 252.

The semiconductor device 20-1 may include an interlayer dielectric B that fills between a transistor stack and a source/drain structure. The semiconductor device 20-1 may include a power line and a signal line in addition to the configurations or components described above.

Referring to FIG. 10, the second insulating pattern 2622 may further extend to cover one side of the second connecting line 2621 relative to the second direction D2 and the third direction D3. The second insulating pattern 2622 may cover one side of the second connecting line 2621 formed at a position opposite the other side of the second connecting line 2621 that contacts the first connecting line 2611.

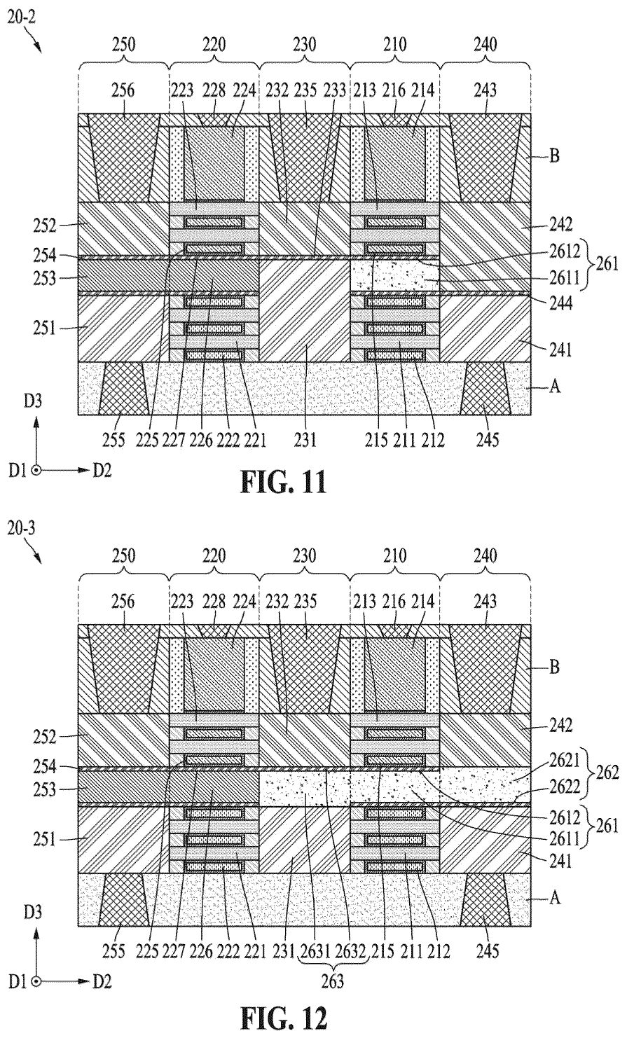

FIG. 11 is a cross-sectional view of a semiconductor device, taken along the cutting line K-K′ of FIG. 8, according to one or more embodiments.

Referring to FIG. 11, a second source/drain structure 240 of a semiconductor device 20-2 may not include a second connecting layer 262 disposed between a second lower source/drain 241 and a second upper source/drain 242.

The second source/drain structure 240 may include the second lower source/drain 241 disposed on the other side of a first lower gate structure 212 and the second upper source/drain 242 disposed on the other side of a first upper gate structure 214.

The second lower source/drain 241 may be formed of silicon (Si) or silicon-germanium (SiGe) doped with p-type impurities such as boron and/or gallium. The second upper source/drain 242 may be formed of silicon (Si) and doped with n-type impurities such as phosphorus and/or arsenic. However, embodiments are not limited thereto.

A level of the second upper source/drain 242 may be higher than a level of a bottom surface of a first connecting layer 261 and the level of the second upper source/drain 242 may be lower than a level of a top surface of the first connecting layer 261. A height of the second upper source/drain 242 along the third direction D3 may be greater (or longer) than heights of a first upper source/drain 232 and a third upper source/drain 252 along the third direction D3.

The height of the second upper source/drain 242 along the third direction D3 perpendicular to the substrate A may be greater (or longer) than a height of the second lower source/drain 241 along the third direction D3 perpendicular to the substrate A.

This structure of the second upper source/drain 242 described above may allow at least a portion of a side of the second upper source/drain 242 to contact at least a portion of a side of the first connecting layer 261. A lower portion of the side of the second upper source/drain 242 may contact a side of the first connecting line 2611 of the first connecting layer 261. An upper portion of the side of the second upper source/drain 242 may contact a side of a first upper channel layer 213.

The second source/drain structure 240 may further include an insulating pattern 244 disposed between the second lower source/drain 241 and the second upper source/drain 242. The insulating pattern 244 may separate the second lower source/drain 241 and the second upper source/drain 242 from each other.

By this structure described above, a first lower source/drain 231 and the second upper source/drain 242 may be directly connected to each other through only the first connecting layer 261.

A second lower source/drain contact 245 may be connected to the second lower source/drain 241. A second upper source/drain contact 243 may be connected to the second upper source/drain 242.

FIG. 12 is a cross-sectional view of a semiconductor device, taken along the cutting line K-K′ of FIG. 8, according to one or more embodiments.

Referring to FIG. 12, a first source/drain structure 230 of a semiconductor device 20-3 may include a third connecting layer 263 disposed between a first lower source/drain 231 and a first upper source/drain 232. The third connecting layer 263 may be formed by extending from a first connecting layer 261.

The third connecting layer 263 may include a third connecting line 2631 and a third insulating pattern 2632. A top or side surface of the third connecting line 2631 relative to the first direction D1 and the third direction D3 may be covered by the third insulating pattern 2632. Of surfaces of the third connecting line 2631, surfaces excluding a surface that contacts the first connecting layer 261 and the first lower source/drain 231 of the first source/drain structure 230 may be covered by the third insulating pattern 2632. At least a portion of a top surface of the first lower source/drain 231 may contact at least a portion of a bottom surface of the third connecting layer 263. A bottom surface of the third connecting line 2631 may contact the first lower source/drain 231. The third insulating pattern 2632 may prevent contact between the third connecting line 2631 and the first upper source/drain 232. At least a portion of a bottom surface of a second upper source/drain 242 may contact at least a portion of a top surface of a second connecting layer 262. The first lower source/drain 231 and the second upper source/drain 242 may be electrically connected via the first connecting layer 261, the second connecting layer 262, and the third connecting layer 263.

The third connecting line 2631 of the third connecting layer 263 may be formed of metal. Alternatively, the third connecting line 2631 may be formed of an electrically conductive material, such as, but not limited to, a conductive metallic material such as cobalt (Co), tungsten (W), ruthenium (Ru), or combinations thereof.

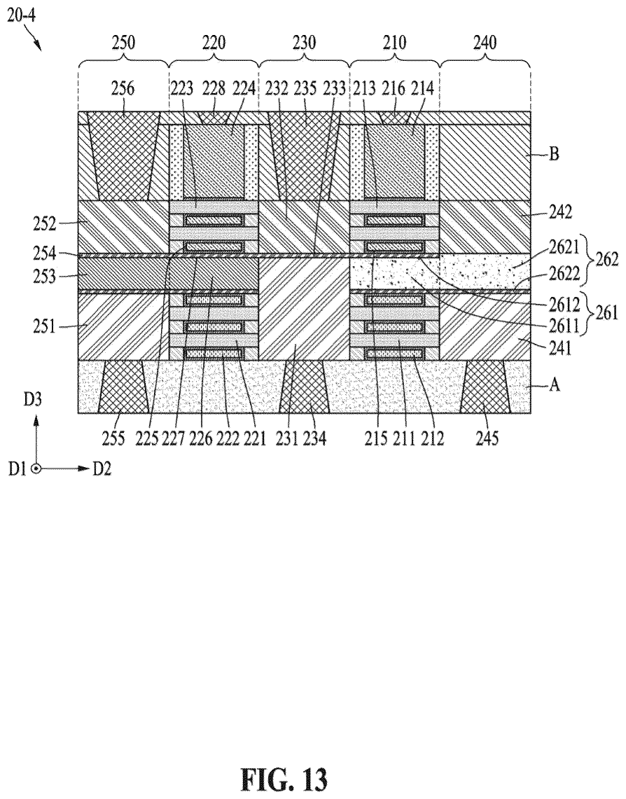

FIG. 13 is a diagram illustrating a semiconductor device according to one or more embodiments.

Referring to FIG. 13, a separate source/drain contact may not be connected to a second upper source/drain 242 of a semiconductor device 20-4. Instead, a first lower source/drain contact 234 may be connected to a first lower source/drain 231 that is electrically connected to the second upper source/drain 242. The first lower source/drain contact 234 may be formed of an electrically conductive material, such as, but not limited to, a conductive metallic material such as cobalt (Co), tungsten (W), ruthenium (Ru), or combinations thereof.

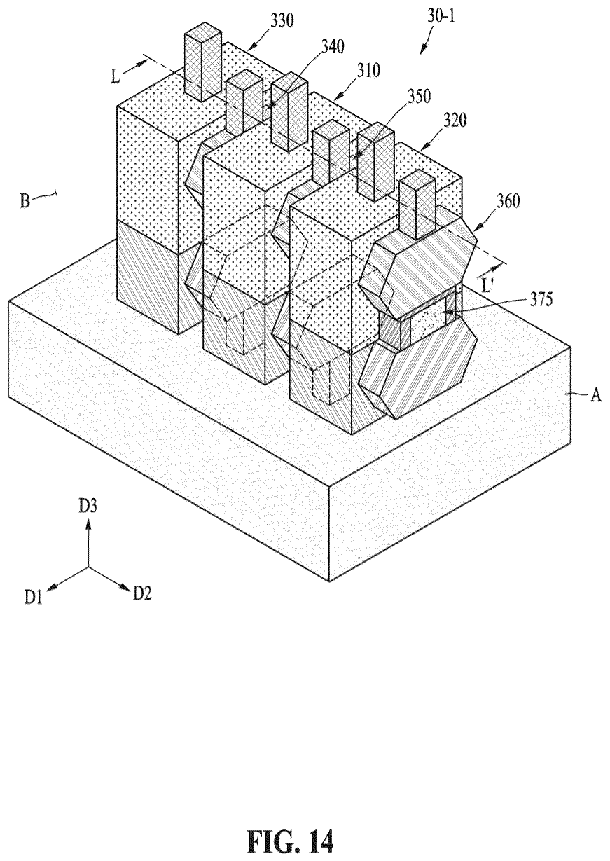

FIG. 14 is a perspective view of a semiconductor device according to one or more embodiments.

Referring to FIG. 14, a semiconductor device 30-1 may include a substrate A, at least one transistor stack (e.g., 310, 320, and 330) formed on the substrate A, and at least one source/drain structure (e.g., 340, 350, and 360) disposed on one side or another side of the at least one transistor stack. The semiconductor device 30-1 may include an interlayer dielectric B that may fill between the at least one transistor stack (e.g., 310, 320, and 330) and the at least one source/drain structure (e.g., 340, 350, and 360).

At least one connecting layer may be formed in the at least one transistor stack or the at least one source/drain structure. For example, a fifth connecting layer 375 described later may be disposed between a third lower source/drain and a third upper source/drain of a third source/drain structure 360.

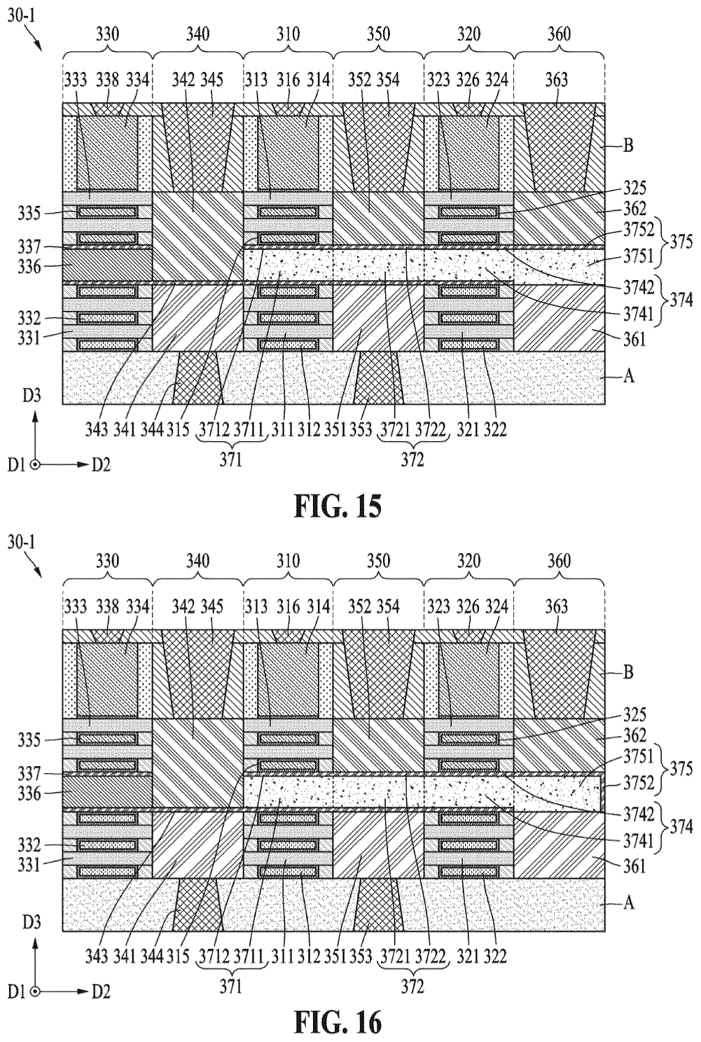

FIGS. 15 and 16 are cross-sectional views of a semiconductor device, taken along a cutting line L-L′ of FIG. 14, according to one or more embodiments.

Referring to FIG. 15, each transistor stack (e.g., 310, 320, and 330) may include a lower transistor formed on the substrate A and an upper transistor formed on the lower transistor. The lower transistor may include at least one lower channel layer (e.g., 311, 321, and 331) and a lower gate structure (e.g., 312, 322, and 332) surrounding the at least one lower channel layer (e.g., 311, 321, and 331). The upper transistor may include at least one upper channel layer (e.g., 313, 323, and 331) and an upper gate structure (e.g., 314, 324, and 334) surrounding the at least one upper channel layer (e.g., 313, 323, and 331).

Each source/drain structure (e.g., 340, 350, and 360) may include a lower source/drain (e.g., 341, 351, and 361) disposed between lower transistors of the respective transistor stacks and an upper source/drain (e.g., 342, 352, and 362) disposed between upper transistors of the respective transistor stacks.

In the semiconductor device 30-1, a first source/drain structure 340, a first transistor stack 310, a second source/drain structure 350, a second transistor stack 320, and a third source/drain structure 360 may be arranged sequentially.

The first transistor stack 310 may include a first lower transistor and a first upper transistor. The first lower transistor may include two first lower channel layers 311 and a first lower gate structure 312 surrounding the two first lower channel layers 311. The first upper transistor may include two first upper channel layers 313 and a first upper gate structure 314 surrounding the two first upper channel layers 313. Although a first lower channel layer and a first upper channel layer are each shown as two channel layers (e.g., the first lower channel layers 311 and the first upper channel layers 313), embodiments are not limited thereto. The first lower channel layer and the first upper channel layer may each be formed as a single channel layer or as a plurality of channel layers including three or more channel layers.

The first lower transistor of the first transistor stack 310 may be a PMOS transistor. The first upper transistor of the first transistor stack 310 may be an NMOS transistor. However, embodiments are not limited thereto.

A top, bottom, or side surfaces of each of the first lower channel layers 311 and the first upper channel layers 313 relative to the first direction D1 and the third direction D3 may be covered by a first gate insulating layer 315.

The first transistor stack 310 may further include a first connecting layer 371. The first connecting layer 371 may be disposed between a first lower channel layer 311 disposed uppermost in the first lower gate structure 312 and a first upper channel layer 313 disposed lowermost in the first upper gate structure 314. The first connecting layer 371 may be surrounded by the first upper gate structure 314 or the first lower gate structure 312.

The first connecting layer 371 may include a first connecting line 3711 and a first insulating pattern 3712. A top surface, bottom surface, or side surfaces of the first connecting line 3711 relative to the first direction D1 and the third direction D3 may be covered by the first insulating pattern 3712. Of surfaces of the first connecting line 3711, surfaces excluding a surface that contacts a second connecting layer 372 and a first upper source/drain 342 of the first source/drain structure 340, which will be described later, may be covered by the first insulating pattern 3712. The first insulating pattern 3712 may prevent direct contact between the first connecting line 3711 and the first upper gate structure 314 or the first lower gate structure 312.

A first transistor contact 316 may be connected to the first transistor stack 310. Although the first transistor contact 316 is shown as connected to the first upper gate structure 314, embodiments are not limited thereto. A first transistor contact may also be connected to the first lower gate structure 312. Alternatively, a transistor contact may be connected to each of the first upper gate structure 314 and the first lower gate structure 312.

The second transistor stack 320 may include a second lower transistor and a second upper transistor. The second lower transistor may include two second lower channel layers 321 and a second lower gate structure 322 surrounding the two second lower channel layers 321. The second upper transistor may include two second upper channel layers 323 and a second upper gate structure 324 surrounding the two second upper channel layers 323. Although a second lower channel layer and a second upper channel layer are each shown as two channel layers (e.g., the second lower channel layers 321 and the second upper channel layers 323), embodiments are not limited thereto. The second lower channel layer and the second upper channel layer may each be formed as a single channel layer or as a plurality of channel layers including three or more channel layers.

The second lower transistor of the second transistor stack 320 may be a PMOS transistor. The second upper transistor of the second transistor stack 320 may be an NMOS transistor. However, embodiments are not limited thereto.

A top, bottom, or side surfaces of each of the second lower channel layers 321 and the second upper channel layers 323 relative to the first direction D1 and the third direction D3 may be covered by a second gate insulating layer 325.

The second transistor stack 320 may further include a fourth connecting layer 374. The fourth connecting layer 374 may be disposed between a second lower channel layer 321 disposed uppermost in the second lower gate structure 322 and a second upper channel layer 323 disposed lowermost in the second upper gate structure 324. The fourth connecting layer 374 may be surrounded by the second upper gate structure 324 or the second lower gate structure 322.

The fourth connecting layer 374 may include a fourth connecting line 3741 and a fourth insulating pattern 3742. A top surface, bottom surface, or side surfaces of the fourth connecting line 3741 relative to the first direction D1 and the third direction D3 may be covered by the fourth insulating pattern 3742. Of surfaces of the fourth connecting line 3741, surfaces excluding a surface that contacts the second connecting layer 372 and a fifth connecting layer 375, which will be described later, may be covered by the fourth insulating pattern 3742. The fourth insulating pattern 3742 may prevent direct contact between the fourth connecting line 3741 and the second upper gate structure 324 or the second lower gate structure 322.

A second transistor contact 326 may be connected to the second transistor stack 320. Although the second transistor contact 326 is shown as connected to the second upper gate structure 324, embodiments are not limited thereto. A second transistor contact may also be connected to the second lower gate structure 322. Alternatively, a transistor contact may be connected to each of the second upper gate structure 324 and the second lower gate structure 322.

The third transistor stack 330 may include a third lower transistor and a third upper transistor. The third lower transistor may include two third lower channel layers 331 and a third lower gate structure 332 surrounding the two third lower channel layers 331. The third upper transistor may include two third upper channel layers 333 and a third upper gate structure 334 surrounding the two third upper channel layers 333. Although a third lower channel layer and a third upper channel layer are each shown as two channel layers (e.g., the third lower channel layers 331 and the third upper channel layers 333), embodiments are not limited thereto. The third lower channel layer and the third upper channel layer may each be formed as a single channel layer or as a plurality of channel layers including three or more channel layers.

The third lower transistor of the third transistor stack 330 may be a PMOS transistor. The third upper transistor of the third transistor stack 330 may be an NMOS transistor. However, embodiments are not limited thereto.

A top, bottom, or side surfaces of each of the third lower channel layers 331 and the third upper channel layers 333 relative to the first direction D1 and the third direction D3 may be covered by a third gate insulating layer 335.

The third transistor stack 330 may further include a first middle insulating layer 336. The first middle insulating layer 336 may be disposed between a third lower channel layer 331 disposed uppermost in the third lower gate structure 332 and a third upper channel layer 333 disposed lowermost in the third upper gate structure 334. A top, bottom, or side surfaces of the first middle insulating layer 336 relative to the first direction D1 and the third direction D3 may be covered by an insulating pattern 337.

A connecting line may be disposed for the third transistor stack 330, as in the first transistor stack 310 or the second transistor stack 320. In this case, the first middle insulating layer 336 may be removed from the third transistor stack 330, and the connecting line may be disposed in place of the first middle insulating layer 336 in a space where the first middle insulating layer 336 is removed.

A third transistor contact 338 may be connected to the third transistor stack 330. Although the third transistor contact 338 is shown as connected to the third upper gate structure 334, embodiments are not limited thereto. A third transistor contact may also be connected to the third lower gate structure 332. Alternatively, a transistor contact may be connected to each of the third upper gate structure 334 and the third lower gate structure 332.

The first source/drain structure 340 may include a first lower source/drain 341 disposed on one side of the first lower gate structure 312 and a first upper source/drain 342 disposed on one side of the first upper gate structure 314. The first lower source/drain 341 may be disposed between the first lower gate structure 312 and the third lower gate structure 332. The first upper source/drain 342 may be disposed between the first upper gate structure 314 and the third upper gate structure 334.

The first lower source/drain 341 may be formed of silicon (Si) or silicon-germanium (SiGe) doped with p-type impurities such as boron and/or gallium. The first upper source/drain 342 may be formed of silicon (Si) and doped with n-type impurities such as phosphorus and/or arsenic. However, embodiments are not limited thereto.

A level of the first upper source/drain 342 may be higher than a level of a bottom surface of the first connecting layer 371 and the level of the first upper source/drain 342 may be lower than a level of a top surface of the first connecting layer 371. A height of the first upper source/drain 342 along the third direction D3 may be greater (or longer) than heights of a second upper source/drain 352 and a third upper source/drain 362, which will be described later, along the third direction D3.

The height of the first upper source/drain 342 along the third direction D3 perpendicular to the substrate A may be greater (or longer) than a height of the first lower source/drain 341 along the third direction D3 perpendicular to the substrate A.

This structure of the first upper source/drain 342 described above may allow at least a portion of a side of the first upper source/drain 342 to contact at least a portion of a side of the first connecting layer 371. A lower portion of the side of the first upper source/drain 342 may contact a side of the first connecting line 3711 of the first connecting layer 371. An upper portion of the side of the first upper source/drain 342 may contact a side of the first upper channel layers 313.

An insulating pattern 343 may be formed between the first lower source/drain 341 and the first upper source/drain 342. The insulating pattern 343 may separate the first lower source/drain 341 and the first upper source/drain 342 from each other.

A first lower source/drain contact 344 may be connected to the first lower source/drain 341. A first upper source/drain contact 345 may be connected to the first upper source/drain 342.

The second source/drain structure 350 may include a second lower source/drain 351 disposed between the first lower gate structure 312 and the second lower gate structure 322, and a second upper source/drain 352 disposed between the first upper gate structure 314 and the second upper gate structure 324.

The second lower source/drain 351 may be formed of silicon (Si) or silicon-germanium (SiGe) doped with p-type impurities such as boron and/or gallium. The second upper source/drain 352 may be formed of silicon (Si) and doped with n-type impurities such as phosphorus and/or arsenic. However, embodiments are not limited thereto.

The second source/drain structure 350 may include the second connecting layer 372 disposed between the second lower source/drain 351 and the second upper source/drain 352. The second connecting layer 372 may include a second connecting line 3721 and a second insulating pattern 3722. A top surface, bottom surface, or side surfaces of the second connecting line 3721 relative to the first direction D1 and the third direction D3 may be covered by the second insulating pattern 3722. Of surfaces of the second connecting line 3721, surfaces excluding a surface that contacts the first connecting layer 371 and the fourth connecting layer 374 may be covered by the second insulating pattern 3722. The second insulating pattern 3722 may prevent the second connecting line 3721 from directly contacting the second lower source/drain 351 and the second upper source/drain 352.

A second lower source/drain contact 353 may be connected to the second lower source/drain 351. A second upper source/drain contact 354 may be connected to the second upper source/drain 352.

The third source/drain structure 360 may include a third lower source/drain 361 disposed on the other side of the second lower gate structure 322 and a third upper source/drain 362 disposed on the other side of the second upper gate structure 324.

The third lower source/drain 361 may be formed of silicon (Si) or silicon-germanium (SiGe) doped with p-type impurities such as boron and/or gallium. The third upper source/drain 362 may be formed of silicon (Si) and doped with n-type impurities such as phosphorus and/or arsenic. However, embodiments are not limited thereto.

The third source/drain structure 360 may include the fifth connecting layer 375 disposed between the third lower source/drain 361 and the third upper source/drain 362. The fifth connecting layer 375 may be formed by extending from the fourth connecting layer 374.

The fifth connecting layer 375 may include a fifth connecting line 3751 and a fifth insulating pattern 3752. A top surface or side surfaces of the fifth connecting line 3751 relative to the first direction D1 and the third direction D3 may be covered by the fifth insulating pattern 3752. Of surfaces of the fifth connecting line 3751, surfaces excluding a surface that contacts the fourth connecting layer 374 and the third lower source/drain 361 of the third source/drain structure 360 may be covered by the fifth insulating pattern 3752. At least a portion of a top surface of the third lower source/drain 361 may contact at least a portion of a bottom surface of the fifth connecting layer 375. A bottom surface of the fifth connecting line 3751 may contact the third lower source/drain 361. The fifth insulating pattern 3752 may prevent contact between the fifth connecting line 3751 and the third upper source/drain 362.

The fifth connecting line 3751 of the fifth connecting layer 375 may be formed of metal. Alternatively, the fifth connecting line 3751 may be formed of an electrically conductive material, such as, but not limited to, a conductive metallic material such as cobalt (Co), tungsten (W), ruthenium (Ru), or combinations thereof.

To the third upper source/drain 362, a third upper source/drain contact 363 may be connected. As the third lower source/drain 361 is electrically connected to the first upper source/drain 342 of the first source/drain structure 340, no separate source/drain contact may be connected to the third lower source/drain 361. However, embodiments are not limited thereto.

The structure of the first transistor stack 310, the second transistor stack 320, the first source/drain structure 340, the second source/drain structure 350, and the third source/drain structure 360 described above may electrically connect the first source/drain structure 340 and the third source/drain structure 360 that are spaced apart by the first transistor stack 310 and the second transistor stack 320.

The first upper source/drain 342 of the first source/drain structure 340 and the third lower source/drain 361 of the third source/drain structure 360 may be electrically connected through the first connecting layer 371 formed in the first transistor stack 310, the second connecting layer 372 formed in the second source/drain structure 350, the fourth connecting layer 374 formed in the second transistor stack 320, and the fifth connecting layer 375 formed in the third source/drain structure 360.

The semiconductor device 30-1 may include an interlayer dielectric B that fills between a transistor stack and a source/drain structure. The semiconductor device 30-1 may include a power line and a signal line in addition to the configurations or components described above.

Referring to FIG. 16, the fifth insulating pattern 3752 may further extend to cover one side of the fifth connecting line 3751 relative to the second direction D2 and the third direction D3. The fifth insulating pattern 3752 may cover one side of the fifth connecting line 3751 formed at a position opposite the other side of the fifth connecting line 3751 that contacts the fourth connecting line 3741.

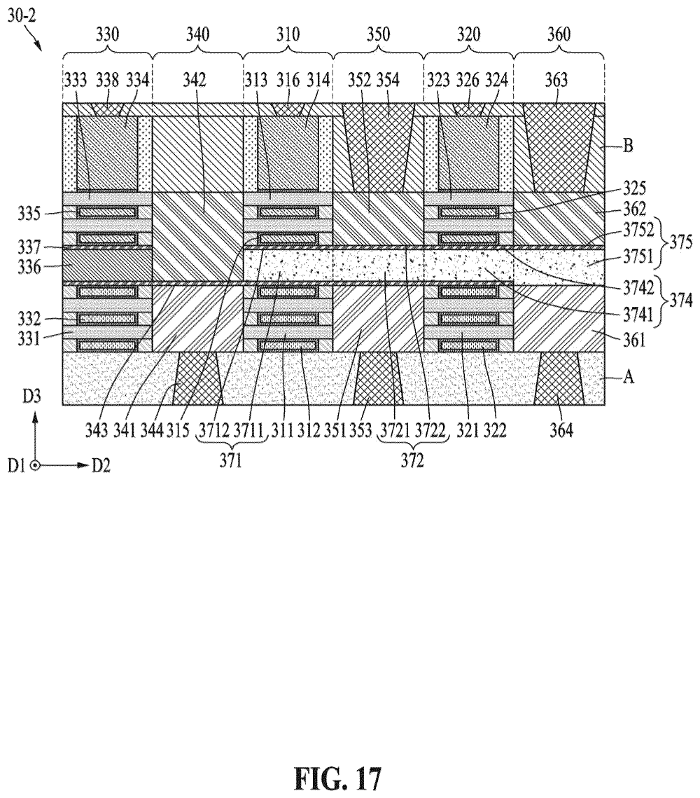

FIG. 17 is a diagram illustrating a semiconductor device according to one or more embodiments.

Referring to FIG. 17, a separate source/drain contact may not be connected to a first upper source/drain 342 of a semiconductor device 30-2. Instead, a third lower source/drain contact 364 may be connected to a third lower source/drain 361 that is electrically connected to the first upper source/drain 342. The third lower source/drain contact 364 may be formed of an electrically conductive material, such as, but not limited to, a conductive metallic material such as cobalt (Co), tungsten (W), ruthenium (Ru), or combinations thereof.

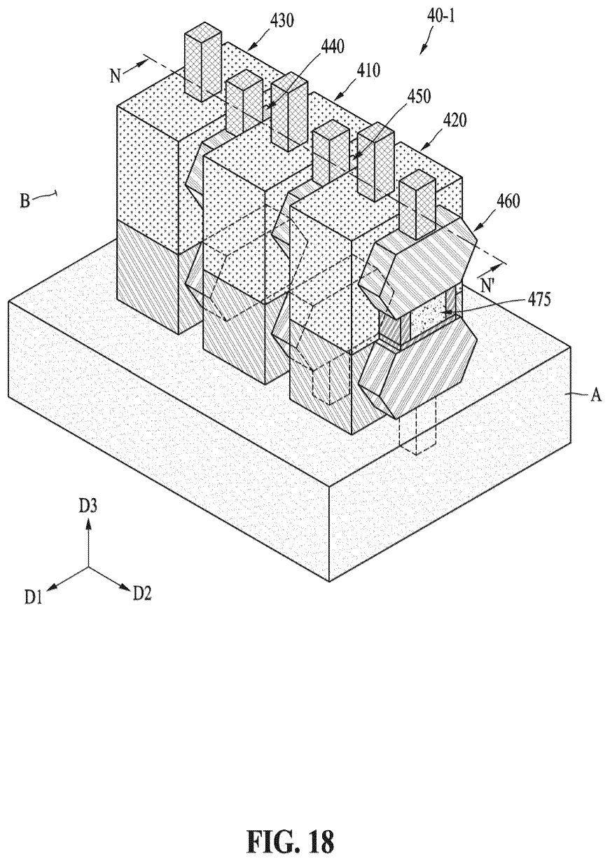

FIG. 18 is a perspective view of a semiconductor device according to one or more embodiments.

Referring to FIG. 18, a semiconductor device 40-1 may include a substrate A, at least one transistor stack (e.g., 410, 420, and 430) formed on the substrate A, and at least one source/drain structure (e.g., 440, 450, and 460) disposed on one side or the other side of the at least one transistor stack. The semiconductor device 40-1 may include an interlayer dielectric B that may fill between the at least one transistor stack (e.g., 410, 420, and 430) and the at least one source/drain structure (e.g., 440, 450, and 460).

At least one connecting layer may be formed in the at least one transistor stack or the at least one source/drain structure. For example, a fifth connecting layer 475 described later may be disposed between a third lower source/drain and a third upper source/drain of a third source/drain structure 460.

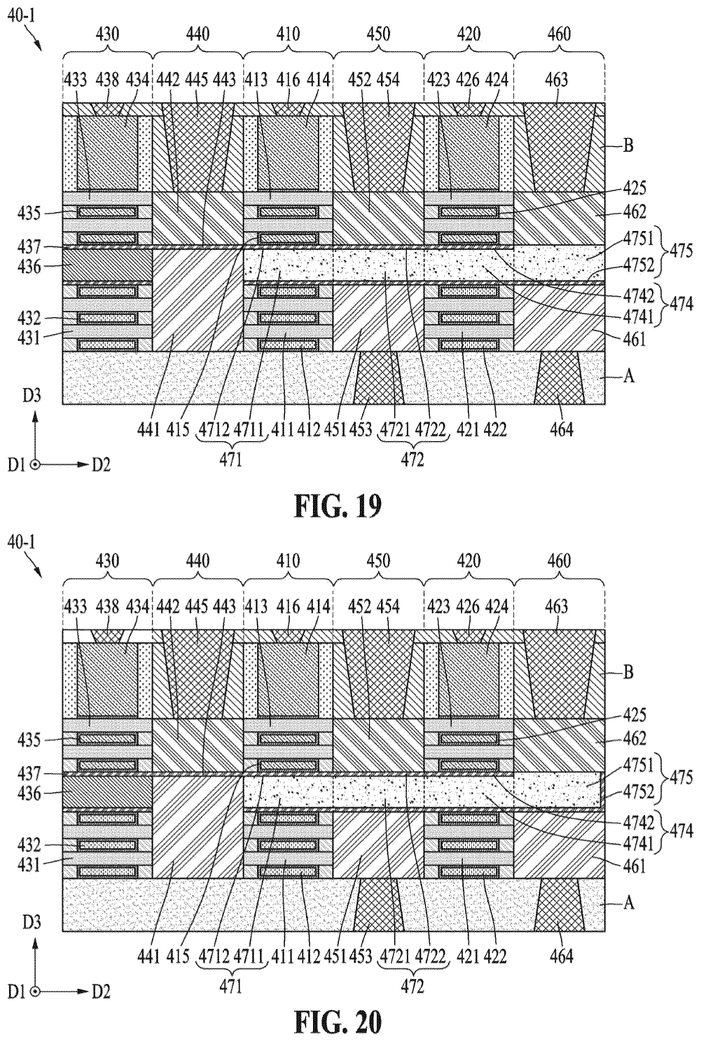

FIGS. 19 and 20 are cross-sectional views of a semiconductor device, taken along a cutting line N-N′ of FIG. 18, according to one or more embodiments.

Referring to FIG. 19, each transistor stack (e.g., 410, 420, and 430) may include a lower transistor formed on the substrate A and an upper transistor formed on the lower transistor. The lower transistor may include at least one lower channel layer (e.g., 411, 421, and 431) and a lower gate structure (e.g., 412, 422, and 432) surrounding the at least one lower channel layer (e.g., 411, 421, and 431). The upper transistor may include at least one upper channel layer (e.g., 413, 423, and 433) and an upper gate structure (e.g., 414, 424, and 434) surrounding the at least one upper channel layer (e.g., 413, 423, and 433).

Each source/drain structure (e.g., 440, 450, and 460) may include a lower source/drain (e.g., 441, 451, and 461) disposed between lower transistors of the respective transistor stacks and an upper source/drain (e.g., 442, 452, and 462) disposed between upper transistors of the respective transistor stacks.

In the semiconductor device 40-1, a first source/drain structure 440, a first transistor stack 410, a second source/drain structure 450, a second transistor stack 420, and a third source/drain structure 460 may be arranged sequentially.

The first transistor stack 410 may include a first lower transistor and a first upper transistor. The first lower transistor may include two first lower channel layers 411 and a first lower gate structure 412 surrounding the two first lower channel layers 411. The first upper transistor may include two first upper channel layers 413 and a first upper gate structure 414 surrounding the two first upper channel layers 413. Although a first lower channel layer and a first upper channel layer are each shown as two channel layers (e.g., the first lower channel layers 411 and the first upper channel layers 413), embodiments are not limited thereto. The first lower channel layer and the first upper channel layer may each be formed as a single channel layer or as a plurality of channel layers including three or more channel layers.

The first lower transistor of the first transistor stack 410 may be a PMOS transistor. The first upper transistor of the first transistor stack 410 may be an NMOS transistor. However, embodiments are not limited thereto.

A top, bottom, or side surfaces of each of the first lower channel layers 411 and the first upper channel layers 413 relative to the first direction D1 and the third direction D3 may be covered by a first gate insulating layer 415.

The first transistor stack 410 may further include a first connecting layer 471. The first connecting layer 471 may be disposed between a first lower channel layer 411 disposed uppermost in the first lower gate structure 412 and a first upper channel layer 413 disposed lowermost in the first upper gate structure 414. The first connecting layer 471 may be surrounded by the first upper gate structure 414 or the first lower gate structure 412.

The first connecting layer 471 may include a first connecting line 4711 and a first insulating pattern 4712. A top surface, bottom surface, or side surfaces of the first connecting line 4711 relative to the first direction D1 and the third direction D3 may be covered by the first insulating pattern 4712. Of surfaces of the first connecting line 4711, surfaces excluding a surface that contacts a second connecting layer 472 and a first lower source/drain 441 of the first source/drain structure 440, which will be described later, may be covered by the first insulating pattern 4712. The first insulating pattern 4712 may prevent direct contact between the first connecting line 4711 and the first upper gate structure 414 or the first lower gate structure 412.

A first transistor contact 416 may be connected to the first transistor stack 410. Although the first transistor contact 416 is shown as connected to the first upper gate structure 414, embodiments are not limited thereto. A first transistor contact may also be connected to the first lower gate structure 412. Alternatively, a transistor contact may be connected to each of the first upper gate structure 414 and the first lower gate structure 412.

The second transistor stack 420 may include a second lower transistor and a second upper transistor. The second lower transistor may include two second lower channel layers 421 and a second lower gate structure 422 surrounding the two second lower channel layers 421. The second upper transistor may include two second upper channel layers 423 and a second upper gate structure 424 surrounding the two second upper channel layers 423. Although a second lower channel layer and a second upper channel layer are each shown as two channel layers (e.g., the second lower channel layers 421 and the second upper channel layers 423), embodiments are not limited thereto. The second lower channel layer and the second upper channel layer may each be formed as a single channel layer or as a plurality of channel layers including three or more channel layers.

The second lower transistor of the second transistor stack 420 may be a PMOS transistor. The second upper transistor of the second transistor stack 420 may be an NMOS transistor. However, embodiments are not limited thereto.

A top, bottom, or side surfaces of each of the second lower channel layers 421 and the second upper channel layers 423 relative to the first direction D1 and the third direction D3 may be covered by a second gate insulating layer 425.

The second transistor stack 420 may further include a fourth connecting layer 474. The fourth connecting layer 474 may be disposed between a second lower channel layer 421 disposed uppermost in the second lower gate structure 422 and a second upper channel layer 423 disposed lowermost in the second upper gate structure 424. The fourth connecting layer 474 may be surrounded by the second upper gate structure 424 or the second lower gate structure 422.

The fourth connecting layer 474 may include a fourth connecting line 4741 and a fourth insulating pattern 4742. A top surface, bottom surface, or side surfaces of the fourth connecting line 4741 relative to the first direction D1 and the third direction D3 may be covered by the fourth insulating pattern 4742. Of surfaces of the fourth connecting line 4741, surfaces excluding a surface that contacts a second connecting layer 472 and a fifth connecting layer 475, which will be described later, may be covered by the fourth insulating pattern 4742. The fourth insulating pattern 4742 may prevent direct contact between the fourth connecting line 4741 and the second upper gate structure 424 or the second lower gate structure 422.

A second transistor contact 426 may be connected to the second transistor stack 420. Although the second transistor contact 426 is shown as connected to the second upper gate structure 424, embodiments are not limited thereto. A second transistor contact may also be connected to the second lower gate structure 422. Alternatively, a transistor contact may be connected to each of the second upper gate structure 424 and the second lower gate structure 422.

A third transistor stack 430 may include a third lower transistor and a third upper transistor. The third lower transistor may include two third lower channel layers 431 and a third lower gate structure 432 surrounding the two third lower channel layers 431. The third upper transistor may include two third upper channel layers 433 and a third upper gate structure 434 surrounding the two third upper channel layers 433. Although a third lower channel layer and a third upper channel layer are each shown as two channel layers (e.g., the third lower channel layers 431 and the third upper channel layers 433), embodiments are not limited thereto. The third lower channel layer and the third upper channel layer may each be formed as a single channel layer or as a plurality of channel layers including three or more channel layers.

The third lower transistor of the third transistor stack 430 may be a PMOS transistor. The third upper transistor of the third transistor stack 430 may be an NMOS transistor. However, embodiments are not limited thereto.

A top, bottom, or side surfaces of each of the third lower channel layers 431 and the third upper channel layers 433 relative to the first direction D1 and the third direction D3 may be covered by a third gate insulating layer 435.

The third transistor stack 430 may further include a first middle insulating layer 436. The first middle insulating layer 436 may be disposed between a third lower channel layer 431 disposed uppermost in the third lower gate structure 432 and a third upper channel layer 433 disposed lowermost in the third upper gate structure 434. A top, bottom, or side surfaces of the first middle insulating layer 436 relative to the first direction D1 and the third direction D3 may be covered by an insulating pattern 437.

A connecting line may be disposed for the third transistor stack 430, as in the first transistor stack 410 or the second transistor stack 420. In this case, the first middle insulating layer 436 may be removed from the third transistor stack 430, and the connecting line may be disposed in place of the first middle insulating layer 436 in a space where the first middle insulating layer 436 is removed.

A third transistor contact 438 may be connected to the third transistor stack 430. Although the third transistor contact 438 is shown as connected to the third upper gate structure 434, embodiments are not limited thereto. A third transistor contact may also be connected to the third lower gate structure 432. Alternatively, a transistor contact may be connected to each of the third upper gate structure 434 and the third lower gate structure 432.

The first source/drain structure 440 may include a first lower source/drain 441 disposed on one side of the first lower gate structure 412 and a first upper source/drain 442 disposed on one side of the first upper gate structure 414. The first lower source/drain 441 may be disposed between the first lower gate structure 412 and the third lower gate structure 432. The first upper source/drain 442 may be disposed between the first upper gate structure 414 and the third upper gate structure 434.

The first lower source/drain 441 may be formed of silicon (Si) or silicon-germanium (SiGe) doped with p-type impurities such as boron and/or gallium. The first upper source/drain 442 may be formed of silicon (Si) and doped with n-type impurities such as phosphorus and/or arsenic. However, embodiments are not limited thereto.

A level of the first lower source/drain 441 may be higher than a level of a bottom surface of the first connecting layer 471 and the level of the first lower source/drain 441 may be lower than a level of a top surface of the first connecting layer 471. A height of the first lower source/drain 441 along the third direction D3 may be greater (or longer) than heights of a second lower source/drain 451 and a third lower source/drain 461, which will be described later, along the third direction D3.

The height of the first lower source/drain 441 along the third direction D3 perpendicular to the substrate A may be greater (or longer) than a height of the first upper source/drain 442 along the third direction D3 perpendicular to the substrate A.

This structure of the first lower source/drain 441 described above may allow at least a portion of a side of the first lower source/drain 441 to contact at least a portion of a side of the first connecting layer 471. An upper portion of the side of the first lower source/drain 441 may contact a side of the first connecting line 4711 of the first connecting layer 471. A lower portion of the side of the first lower source/drain 441 may contact a side of the first lower channel layers 411.

An insulating pattern 443 may be formed between the first lower source/drain 441 and the first upper source/drain 442. The insulating pattern 443 may separate the first lower source/drain 441 and the first upper source/drain 442 from each other.

A first upper source/drain contact 445 may be connected to the first upper source/drain 442. As will be described later, as the first lower source/drain 441 is electrically connected to a third upper source/drain 462 of the third source/drain structure 460, no separate source/drain contact may be connected to the first lower source/drain 441. However, embodiments are not limited thereto.

The second source/drain structure 450 may include a second lower source/drain 451 disposed between the first lower gate structure 412 and the second lower gate structure 422, and a second upper source/drain 452 disposed between the first upper gate structure 414 and the second upper gate structure 424.

The second lower source/drain 451 may be formed of silicon (Si) or silicon-germanium (SiGe) doped with p-type impurities such as boron and/or gallium. The second upper source/drain 452 may be formed of silicon (Si) and doped with n-type impurities such as phosphorus and/or arsenic. However, embodiments are not limited thereto.

The second source/drain structure 450 may include the second connecting layer 472 disposed between the second lower source/drain 451 and the second upper source/drain 452. The second connecting layer 472 may include a second connecting line 4721 and a second insulating pattern 4722. A top surface, bottom surface, or side surfaces of the second connecting line 4721 relative to the first direction D1 and the third direction D3 may be covered by the second insulating pattern 4722. Of surfaces of the second connecting line 4721, surfaces excluding a surface that contacts the first connecting layer 471 and the fourth connecting layer 474 may be covered by the second insulating pattern 4722. The second insulating pattern 4722 may prevent the second connecting line 4721 from directly contacting the second lower source/drain 451 and the second upper source/drain 452.

A second lower source/drain contact 453 may be connected to the second lower source/drain 451. A second upper source/drain contact 454 may be connected to the second upper source/drain 452.

The third source/drain structure 460 may include a third lower source/drain 461 disposed on the other side of the second lower gate structure 422 and a third upper source/drain 462 disposed on the other side of the second upper gate structure 424.

The third lower source/drain 461 may be formed of silicon (Si) or silicon-germanium (SiGe) doped with p-type impurities such as boron and/or gallium. The third upper source/drain 462 may be formed of silicon (Si) and doped with n-type impurities such as phosphorus and/or arsenic. However, embodiments are not limited thereto.

The third source/drain structure 460 may include the fifth connecting layer 475 disposed between the third lower source/drain 461 and the third upper source/drain 462. The fifth connecting layer 475 may be formed by extending from the fourth connecting layer 474.

The fifth connecting layer 475 may include a fifth connecting line 4751 and a fifth insulating pattern 4752. A bottom surface or side surfaces of the fifth connecting line 4751 relative to the first direction D1 and the third direction D3 may be covered by the fifth insulating pattern 4752. Of surfaces of the fifth connecting line 4751, surfaces excluding a surface that contacts the fourth connecting layer 474 and the third upper source/drain 462 of the third source/drain structure 460 may be covered by the fifth insulating pattern 4752. At least a portion of a bottom surface of the third upper source/drain 462 may contact at least a portion of a top surface of the fifth connecting layer 475. A top surface of the fifth connecting line 4751 may contact the third upper source/drain 462. The fifth insulating pattern 4752 may prevent contact between the fifth connecting line 4751 and the third lower source/drain 461.

The fifth connecting line 4751 of the fifth connecting layer 475 may be formed of metal. Alternatively, the fifth connecting line 4751 may be formed of an electrically conductive material, such as, but not limited to, a conductive metallic material such as cobalt (Co), tungsten (W), ruthenium (Ru), or combinations thereof.

A third upper source/drain contact 463 may be connected to the third upper source/drain 462. A third lower source/drain contact 464 may be connected to the third lower source/drain 461.

The structure of the first transistor stack 410, the second transistor stack 420, the first source/drain structure 440, the second source/drain structure 450, and the third source/drain structure 460 described above may electrically connect the first source/drain structure 440 and the third source/drain structure 460 that are spaced apart by the first transistor stack 410 and the second transistor stack 420.

The first lower source/drain 441 of the first source/drain structure 440 and the third upper source/drain 462 of the third source/drain structure 460 may be electrically connected through the first connecting layer 471 formed in the first transistor stack 410, the second connecting layer 472 formed in the second source/drain structure 450, the fourth connecting layer 474 formed in the second transistor stack 420, and the fifth connecting layer 475 formed in the third source/drain structure 460.

The semiconductor device 40-1 may include an interlayer dielectric B that fills between a transistor stack and a source/drain structure. The semiconductor device 40-1 may include a power line and a signal line in addition to the configurations or components described above.

Referring to FIG. 20, the fifth insulating pattern 4752 may further extend to cover one side of the fifth connecting line 4751 relative to the second direction D2 and the third direction D3. The fifth insulating pattern 4752 may cover one side of the fifth connecting line 4751 formed at a position opposite the other side of the fifth connecting line 4751 that contacts the fourth connecting line 4741.

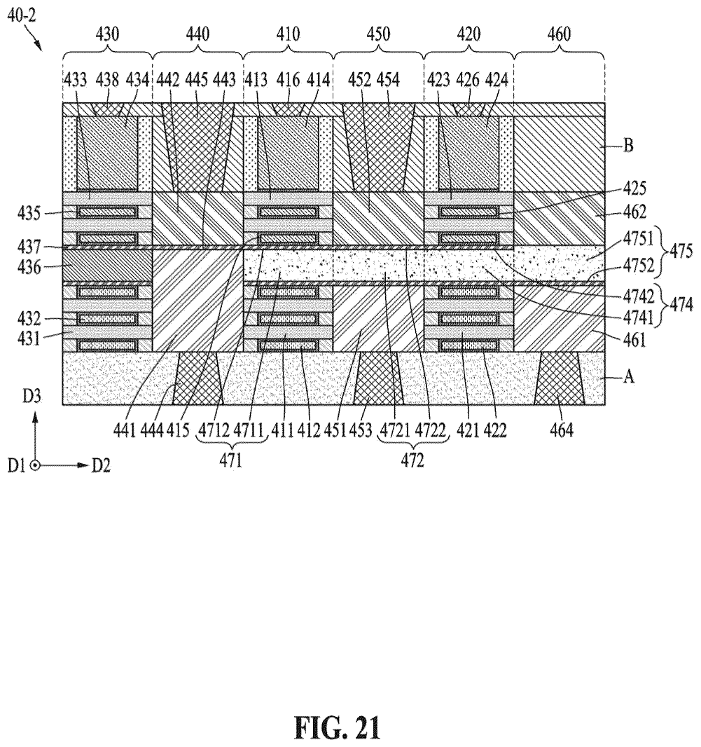

FIG. 21 is a diagram illustrating a semiconductor device according to one or more embodiments.

Referring to FIG. 21, a separate source/drain contact may not be connected to a third upper source/drain 462 of a semiconductor device 40-2. Instead, a first lower source/drain contact 444 may be connected to a first lower source/drain 441 that is electrically connected to the third upper source/drain 462. The first lower source/drain contact 444 may be formed of an electrically conductive material, such as, but not limited to, a conductive metallic material such as cobalt (Co), tungsten (W), ruthenium (Ru), or combinations thereof.

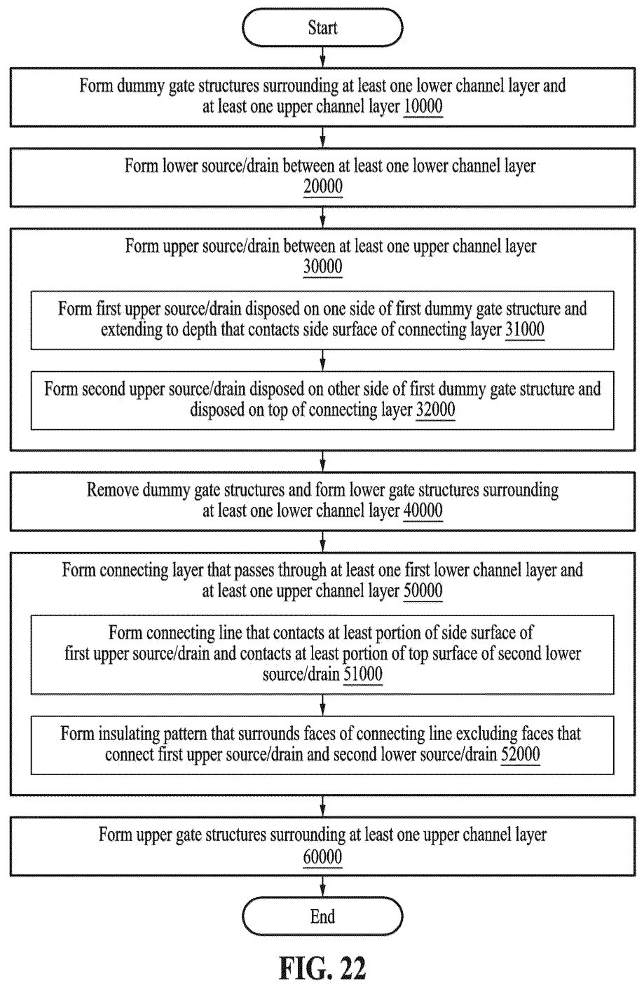

FIG. 22 is a flowchart illustrating a method of manufacturing a semiconductor device according to one or more embodiments.

Referring to FIG. 22, a method of manufacturing a semiconductor device may include operation 10000 of forming a plurality of dummy gate structures each surrounding at least one lower channel layer and at least one upper channel layer, operation 20000 of forming a lower source/drain between at least one lower channel layer, operation 30000 of forming an upper source/drain between at least one upper channel layer, operation 40000 of removing the dummy gate structures and forming a plurality of lower gate structures surrounding the at least one lower channel layer, operation 50000 of forming a connecting layer passing between at least one first lower channel layer and at least one first upper channel layer of a first dummy gate structure, and operation 60000 of forming a plurality of upper gate structures surrounding the at least one upper channel layer.

The lower source/drain and the upper source/drain, which are spaced apart from each other relative to the first dummy gate structure, may be electrically connected via the connecting layer.

Operation 30000 of forming the upper source/drain may include operation 31000 of forming a first upper source/drain disposed on one side of the first dummy gate structure and extending to a depth that may contact a side surface of the connecting layer, and operation 32000 of forming a second upper source/drain disposed on the other side of the first dummy gate structure and disposed on connecting layer.

Operation 50000 of forming the connecting layer may include operation 51000 of forming a connecting line operation 52000 of forming an insulating pattern. In operation 51000 of forming the connecting line, at least a portion of a side surface of the connecting line may contact at least a portion of a side of the first upper source/drain, and at least a portion of a bottom surface of the connecting line may contact at least a portion of a top surface of a second lower source/drain. In step 52000 of forming the insulating pattern, the insulating pattern may cover surfaces of the connecting line excluding surfaces that contact the first upper source/drain and the second lower source/drain.

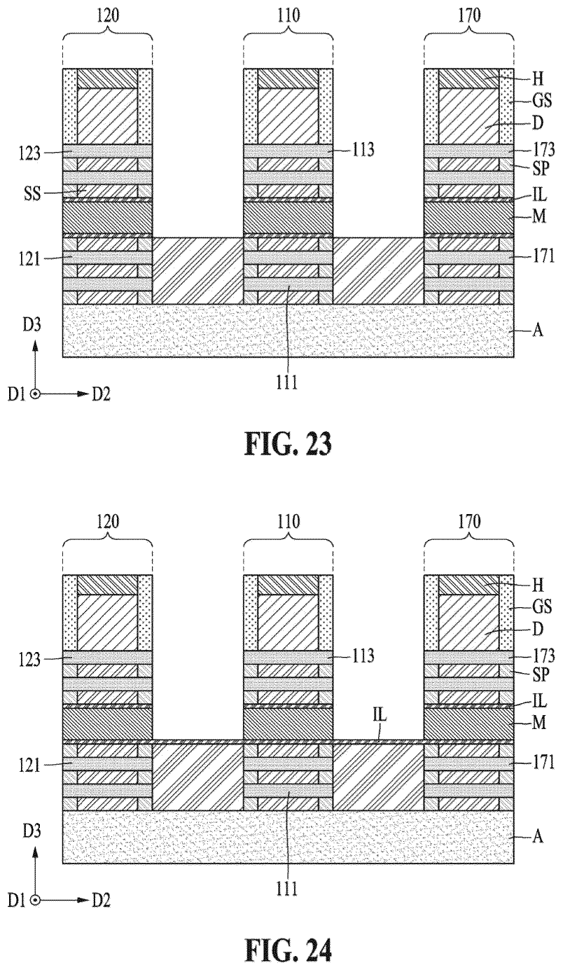

FIGS. 23 through 39B are diagrams illustrating a process of manufacturing a semiconductor device according to one or more embodiments.

Referring to FIG. 23, each transistor stack (e.g., 110, 120, and 170) disposed on a substrate A may be formed with at least one lower channel layer (e.g., 111, 121, and 171), at least one upper channel layer (e.g., 113, 123, and 173), and a dummy gate structure D surrounding the upper and lower channel layers. A hardmask pattern H may be formed on a top surface of the dummy gate structure D, and a gate spacer GS may be formed on side surfaces of the dummy gate structure D. A middle insulating layer M may be formed between the upper channel layer and the lower channel layer. The middle insulating layer M may be covered by an insulating pattern IL. A sacrificial layer SS may be formed between the channel layers spaced apart along the third direction D3. On both sides of the sacrificial layer SS, internal spacers SP may be formed. The internal spacers SP may be formed by, for example, ALD, plasma-enhanced ALD (PEALD), CVD, PECVD, or a combination thereof. However, embodiments are not limited thereto. A lower source/drain may be formed between lower channel layers spaced apart along the second direction D2.

Referring to FIG. 24, the insulating pattern IL may be additionally formed on the lower source/drain.

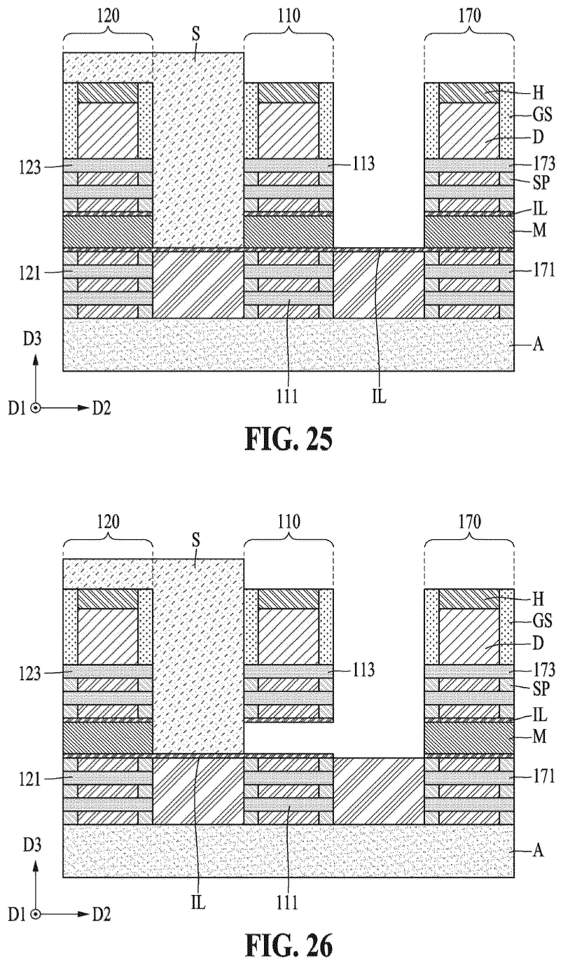

Referring to FIG. 25, a sacrificial pattern S may be deposited to fill an upper side of the second transistor stack 120 and an upper side of the lower source/drain disposed between the first transistor stack 110 and the second transistor stack 120. The sacrificial pattern S may be a spin on hardmask (SOH). Accordingly, the second transistor stack 120 and the lower source/drain disposed between the first transistor stack 110 and the second transistor stack 120 may be covered, while the first transistor stack 110 and the lower source/drain disposed between the first transistor stack 110 and the third transistor stack 170 may remain exposed.

Referring to FIG. 26, a portion of the middle insulating layer disposed between the upper channel layer 113 and the lower channel layer 111 of the first transistor stack 110 may be etched. A portion of the insulating pattern disposed on the lower source/drain disposed between the first transistor stack 110 and the third transistor stack 170 may also be etched.

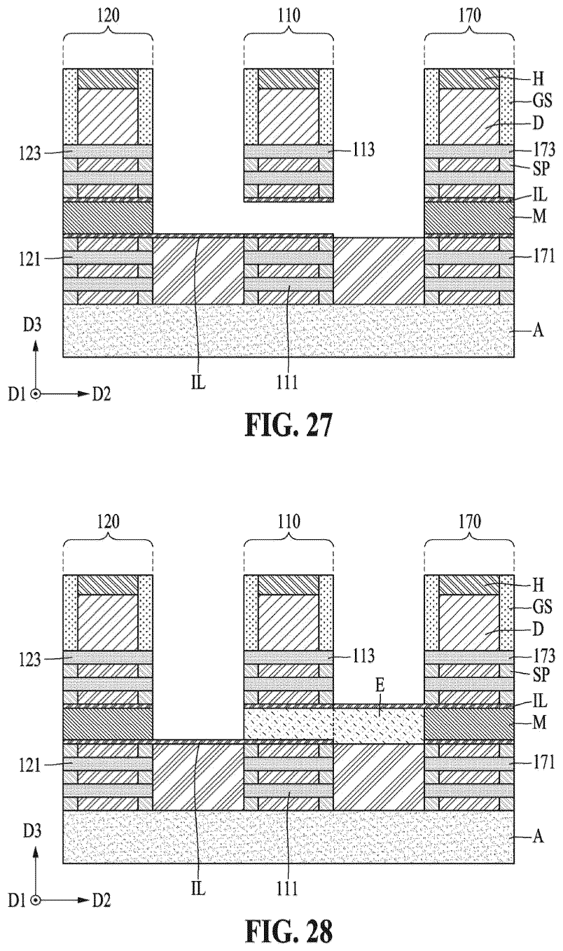

Referring to FIG. 27, the sacrificial pattern S may be removed. For example, the sacrificial pattern S may be removed through an SOH ashing process.

Referring to FIG. 28, a dummy insulating layer E may be formed between the upper channel layer 113 and the lower channel layer 111 of the first transistor stack 110. The dummy insulating layer E and the insulating pattern IL may also be formed on an upper side of the lower source/drain disposed between the first transistor stack 110 and the third transistor stack 170.

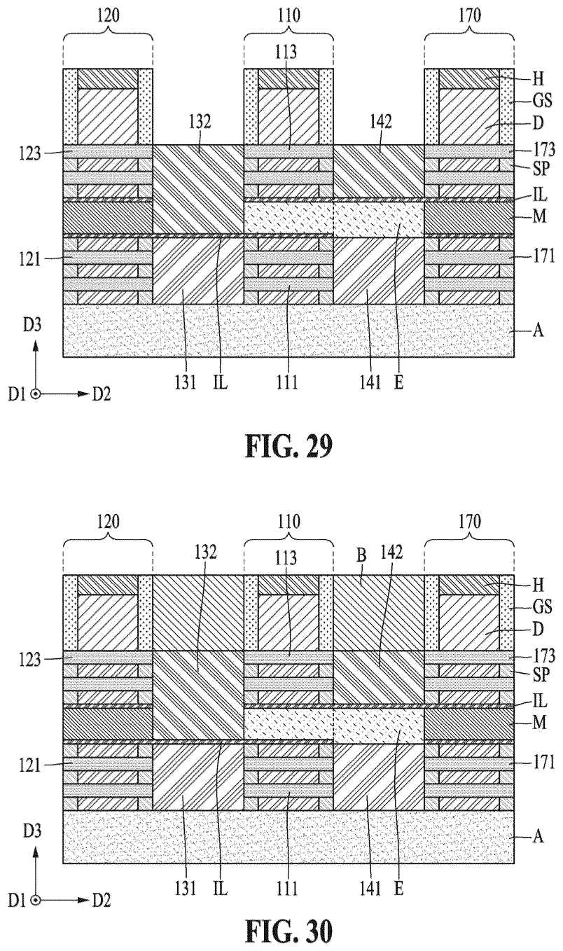

Referring to FIG. 29, a first lower source/drain 131 and a first upper source/drain 132 may be formed between the first transistor stack 110 and the second transistor stack 120. The first lower source/drain 131 and the first upper source/drain 132 may be separated from each other by the insulating pattern IL. A second lower source/drain 141 and a second upper source/drain 142 may be formed between the first transistor stack 110 and the third transistor stack 170. The second lower source/drain 141 and the second upper source/drain 142 may be separated from each other by the dummy insulating layer E and the insulating pattern IL.

A height of the first upper source/drain 132 along the third direction D3 may be formed to be greater (of longer) than a height of the second upper source/drain 142 along the third direction D3. The height of the first upper source/drain 132 along the third direction D3 perpendicular to the substrate A may be formed to be greater (of longer) than a height of the first lower source/drain 131 along the third direction D3 perpendicular to the substrate A.

Referring to FIG. 30, an interlayer dielectric B may be deposited on the first upper source/drain 132 and the second upper source/drain 142. The interlayer dielectric B may separate the upper sources/drains 132 and 142 from each other and from other circuit elements.

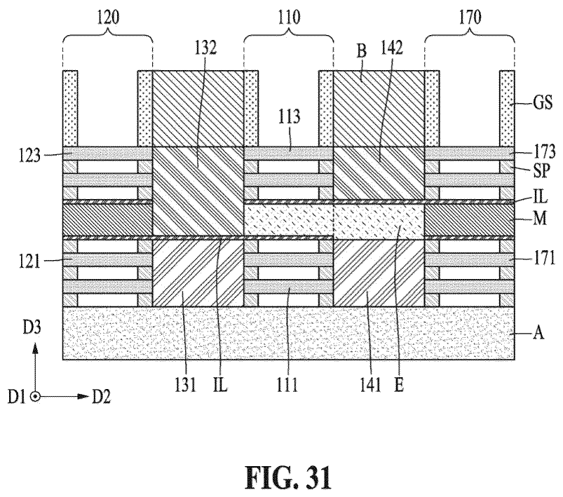

Referring to FIG. 31, the hardmask pattern H, the dummy gate structure D, and sacrificial layers disposed on an upper portion may be removed.

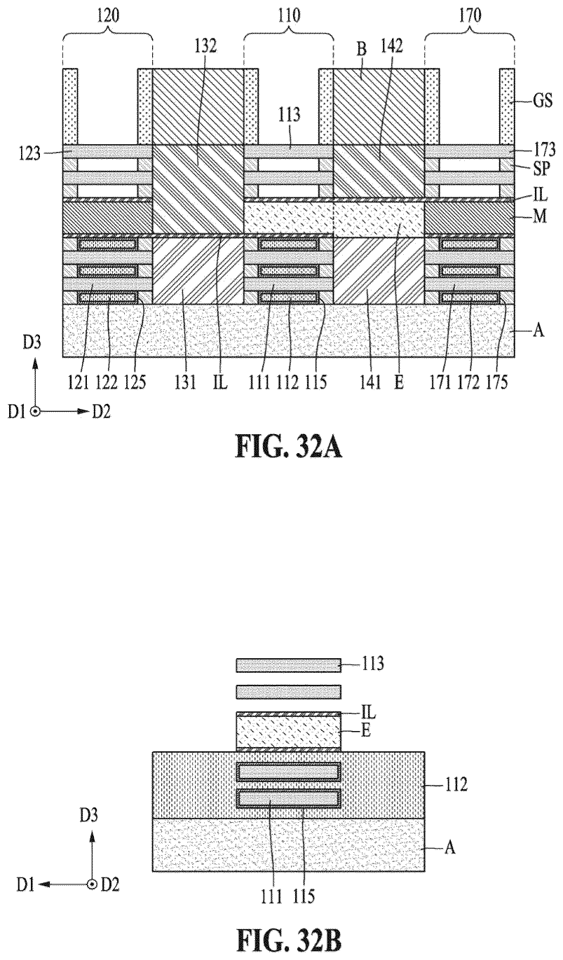

Referring to FIGS. 32A and 32B, lower gate structures 112, 122, and 172 may be formed on the lower channel layers 111, 121, and 171. In addition, gate insulating layers 115, 125, and 175 may be formed to surround the lower channel layers 111, 121, and 171, respectively. For the first transistor stack 110, a first lower gate structure 112 may be formed to surround the first lower channel layer 111. A first gate insulating layer 115 may be formed between the first lower channel layer 111 and the first lower gate structure 112. The dummy insulating layer E may remain between the first lower channel layer 111 and the first upper channel layer 113.

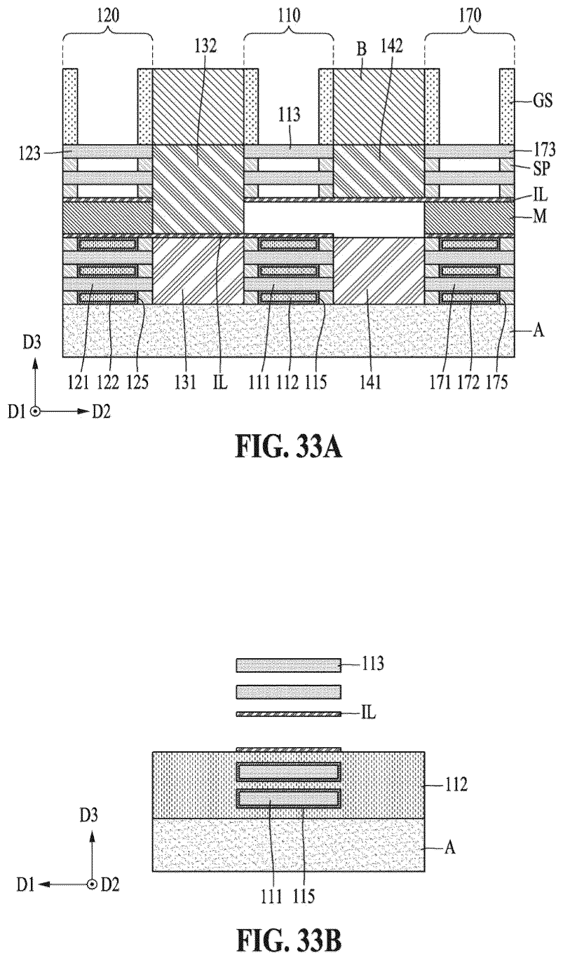

Referring to FIGS. 33A and 33B, the dummy insulating layer E disposed between the first lower channel layer 111 and the first upper channel layer 113 may be removed. The dummy insulating layer E disposed between the second lower source/drain 141 and the second upper source/drain 142 may also be removed.

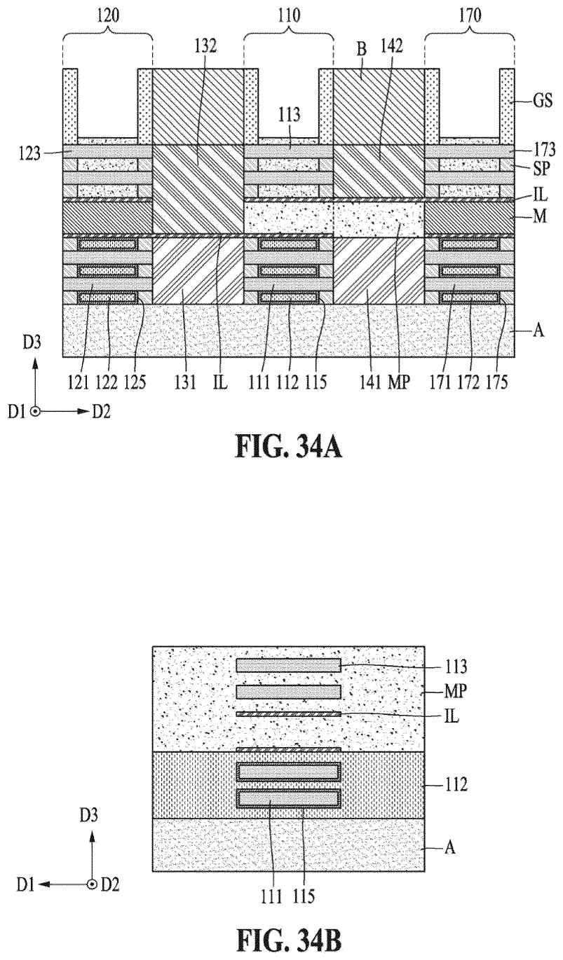

Referring to FIGS. 34A and 34B, a space from which the dummy insulating layer E is removed and a space between the upper channel layers 113, 123, and 173 may be filled with a metallic or conductive material MP.

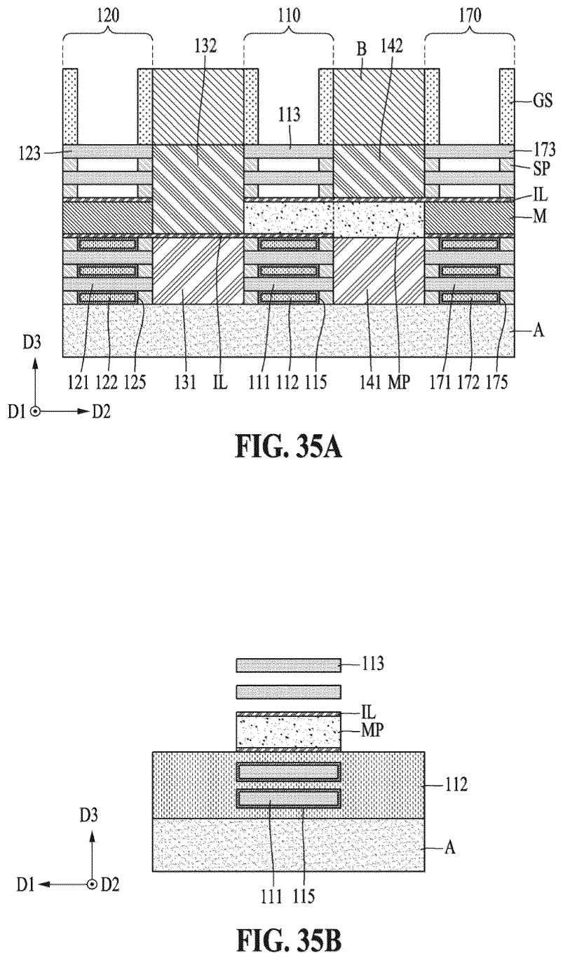

Referring to FIGS. 35A and 35B, the metallic or conductive material MP present in the space between the upper channel layers 113, 123, and 173 may be removed. In addition, the metallic or conductive material MP filled in the space from which the dummy insulating layer is removed may have the same width as that of the insulating pattern IL along the first direction D1.

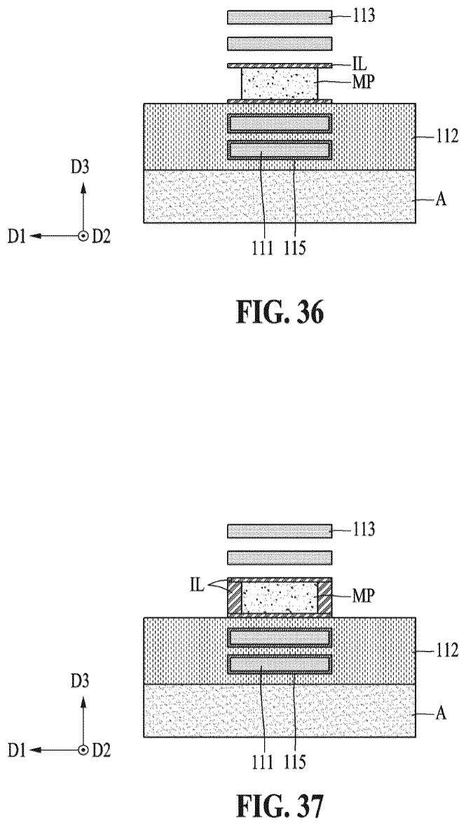

Referring to FIG. 36, the metallic or conductive material MP on both sides in the first direction D1 may be partially removed.

Referring to FIG. 37, both sides of the metallic or conductive material MP relative to the first direction D1 may be additionally covered by the insulating pattern IL. A top surface, bottom surface, and both side surfaces of the metallic or conductive material MP relative to the first direction D1 and the third direction D3 may be covered by the insulating pattern IL.

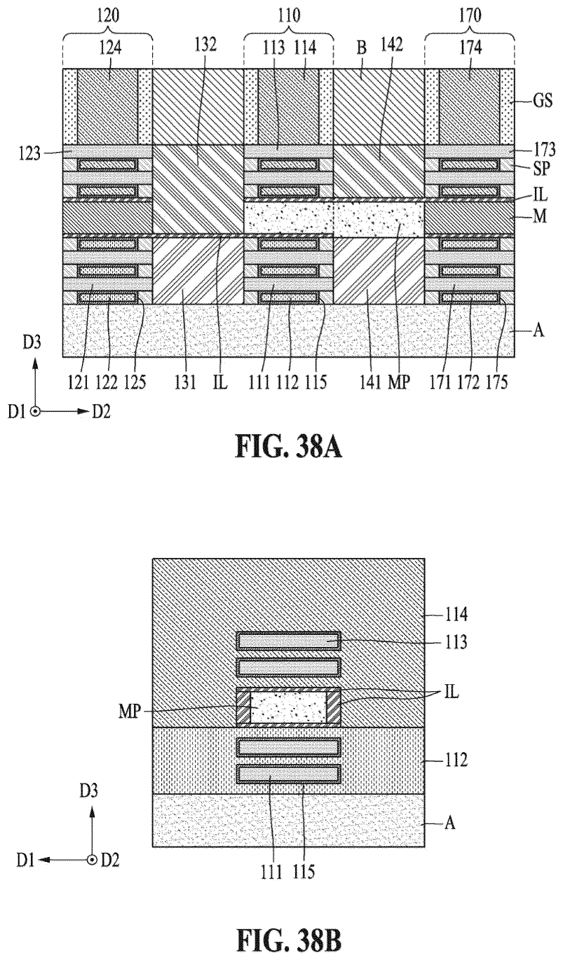

Referring to FIGS. 38A and 38B, upper gate structures 114, 124, and 174 may be formed on the upper channel layers 113, 123, and 173. In addition, gate insulating layers 115, 125, and 175 may be formed to surround the upper channel layers 113, 123, and 173, respectively. For the first transistor stack 110, a first upper gate structure 114 may be formed to surround the first upper channel layer 113. A first gate insulating layer 115 may be formed between the first upper channel layer 113 and the first upper gate structure 114. The first upper gate structure 114 may also surround the metallic or conductive material MP.

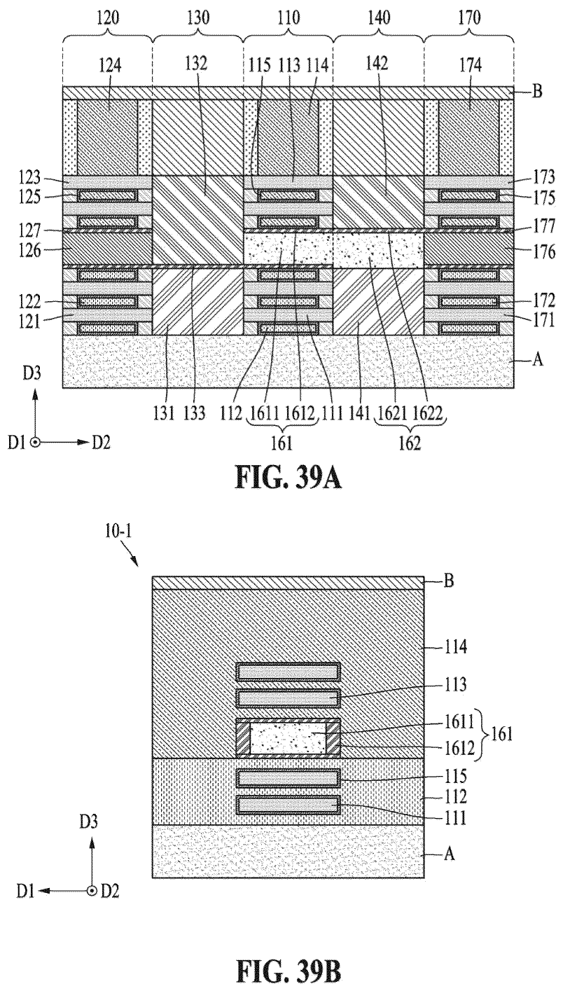

Referring to FIGS. 39A and 39B, an interlayer dielectric B may be additionally deposited to cover an upper side of the first transistor stack 110, the second transistor stack 120, and the third transistor stack 170. The metallic or conductive material MP may be defined as a first connecting line 1611 of a first connecting layer 161 and a second connecting line 1621 of a second connecting layer 162. The insulating pattern IL may be defined as a first insulating pattern 1612, a second insulating pattern 1622, insulating patterns 126, 133, and 177, and the like. The middle insulating layer M may be defined as a first middle insulating layer 126 of the second transistor stack 120 and a third middle insulating layer 176 of the third transistor stack 170.

The first transistor stack 110 may include the first lower channel layer 111, the first lower gate structure 112, the first upper channel layer 113, the first upper gate structure 114, the first gate insulating layer 115, and the first connecting layer 161. The first connecting layer 161 may include the first connecting line 1611 and the first insulating pattern 1612. Although a width of the first connecting line 1611 along the first direction D1 is shown as being less than a width of the first lower channel layer 111 or a width of the first upper channel layer 113, embodiments are not limited thereto. The width of the first connecting line 1611 along the first direction D1 may be greater than the width of the first lower channel layer 111 or the width of the first upper channel layer 113. Alternatively, the width of the first connecting line 1611 along the first direction D1 may be the same as the width of the first lower channel layer 111 or the width of the first upper channel layer 113.

This structure described above may electrically connect the first upper source/drain 132 disposed on one side of the first transistor stack 110 and the second lower source/drain 141 disposed on the other side of the first transistor stack 110 via the first connecting layer 161 inside the first transistor stack 110 and the second connecting layer 162 inside the second source/drain structure 140.

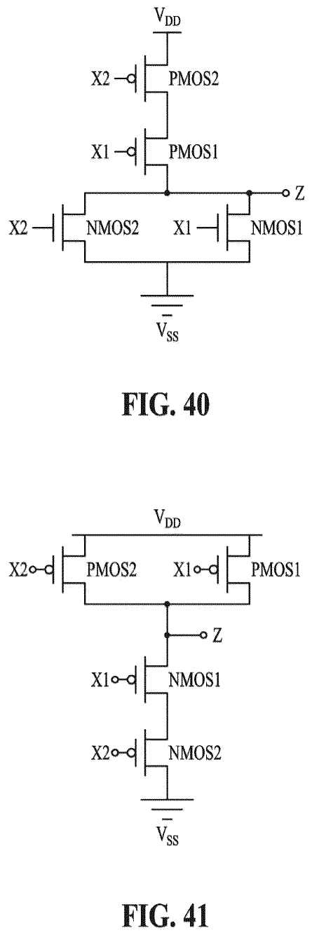

FIGS. 40 and 41 are circuit diagrams illustrating a circuit formed by a semiconductor device according to one or more embodiments.

The semiconductor device 10-1 described above with reference to FIGS. 2A and 2B may form a NOR gate circuit shown in FIG. 40. The first lower transistor (e.g., PMOS1 in FIG. 40) of the first transistor stack 110 and the second lower transistor (e.g., PMOS2 in FIG. 40) of the second transistor stack 120 may be formed as PMOS transistors, and the first upper transistor (e.g., NMOS1 in FIG. 40) of the first transistor stack 110 and the second upper transistor (e.g., NMOS2 in FIG. 40) of the second transistor stack 120 may be formed as NMOS transistors. The first upper source/drain 132 disposed between the first upper transistor and the second upper transistor and the second lower source/drain 141 disposed on the other side of the first lower transistor may be electrically connected via the connecting layers 161 and 162. A gate structure of the first upper transistor and the first lower transistor may receive a first input signal X1. A gate structure of the second upper transistor and the second lower transistor may receive a second input signal X2. This structure described above may allow the semiconductor device 10-1 to generate an output signal Z corresponding to a result of an NOR operation on the input signals X1 and X2 at a node corresponding to an extended source/drain.

The semiconductor device 10-5 described above with reference to FIGS. 7A and 7B may form a NAND gate circuit shown in FIG. 41. The first lower transistor (e.g., NMOS1 in FIG. 41) of the first transistor stack 110 and the second lower transistor (e.g., NMOS2 in FIG. 41) of the second transistor stack 120 may be formed as NMOS transistors, and the first upper transistor (e.g., PMOS1 in FIG. 41) of the first transistor stack 110 and the second upper transistor (e.g., PMOS2 in FIG. 41) of the second transistor stack 120 may be formed as PMOS transistors. The first upper source/drain 132 disposed between the first upper transistor and the second upper transistor and the second lower source/drain 141 disposed on the other side of the first lower transistor may be electrically connected via the connecting layers 161 and 162. A gate structure of the first upper transistor and the first lower transistor may receive a first input signal X1. A gate structure of the second upper transistor and the second lower transistor may receive a second input signal X2. This structure described above may allow the semiconductor device 10-5 to generate an output signal Z corresponding to a result of a NAND operation on the input signals X1 and X2 at a node corresponding to an extended source/drain.

As described above, according to one or more embodiments, a semiconductor device and a method of manufacturing the semiconductor device may connect sources/drains spaced apart from each other through a connecting layer disposed between an upper channel layer and a lower channel layer of a transistor stack to improve space efficiency.

Further, according to one or more embodiments, the semiconductor device and the method of manufacturing the semiconductor device may directly connect sources/drains spaced apart from each other through a connecting layer, instead of an elongated via, to effectively prevent unnecessary capacitance from being generated. Therefore, according to one or more embodiments, the semiconductor device and the method of manufacturing the semiconductor device may realize the optimal performance or optimal speed.

The semiconductor device and method of manufacturing the semiconductor device, according to one or more embodiments may improve space efficiency by connecting sources/drains spaced apart from each other through a connecting layer disposed between an upper channel layer and a lower channel layer of a transistor stack.

The semiconductor device and method of manufacturing the semiconductor device, according to one or more embodiments may effectively prevent unnecessary capacitance from being generated by directly connecting sources/drains spaced apart from each other through a connecting layer instead of an elongated via.

The semiconductor device and method of manufacturing the semiconductor device, according to one or more embodiments may realize optimal performance or optimal speed.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A semiconductor device, comprising:
a substrate;
a transistor stack on the substrate;
a first source/drain structure on a first side of the transistor stack; and
a second source/drain structure on a second side of the transistor stack,
wherein the transistor stack comprises:
a lower transistor on the substrate, the lower transistor comprising a lower channel layer and a lower gate structure surrounding the lower channel layer;
an upper transistor on the lower transistor, the upper transistor comprising an upper channel layer and an upper gate structure surrounding the upper channel layer, and
a first connecting layer between the lower gate structure and the upper gate structure, and
wherein the first source/drain structure and the second source/drain structure are connected via the first connecting layer.

2. The semiconductor device of claim 1, wherein the first source/drain structure comprises:
a first lower source/drain on a first side of the lower gate structure; and
a first upper source/drain on a first side of the upper gate structure, and
wherein the second source/drain structure comprises:
a second lower source/drain on a second side of the lower gate structure; and
a second upper source/drain on a second side of the upper gate structure, and
wherein the first connecting layer connects the first upper source/drain and the second lower source/drain, or the first lower source/drain and the second upper source/drain.

3. The semiconductor device of claim 2, further comprising:
a second connecting layer extending from the first connecting layer and between the second lower source/drain and the second upper source/drain.

4. The semiconductor device of claim 3, wherein, a side surface of the first upper source/drain contacts a side surface of the first connecting layer, and
wherein a top surface of the second lower source/drain contacts a bottom surface of the second connecting layer.

5. The semiconductor device of claim 4, wherein a level of the first upper source/drain is higher than a level of a bottom surface of the first connecting layer and the level of the first upper source/drain is lower than a level of a top surface of the first connecting layer.

6. The semiconductor device of claim 5, wherein the level of the first upper source/drain in the vertical direction is greater than a level of the first lower source/drain in the vertical direction.

7. The semiconductor device of claim 3, wherein a side surface of the first lower source/drain contacts a side surface of the first connecting layer; and
wherein a bottom surface of the second upper source/drain contacts a top surface of the second connecting layer.

8. The semiconductor device of claim 7, wherein a level of a top surface of the first lower source/drain is higher than a level of a top surface of the first connecting layer and a level of a top surface of the first lower source/drain is lower than a level of a bottom surface of the first connecting layer.

9. The semiconductor device of claim 8, wherein the level of the first lower source/drain in the vertical direction greater than a level of the first upper source/drain in the vertical direction.

10. The semiconductor device of claim 3, wherein the first connecting layer comprises:
a first connecting line; and
a first insulating pattern surrounding surfaces of the first connecting line excluding a surface that contacts the second connecting layer and the first source/drain structure, and
wherein the second connecting layer comprises:
a second connecting line; and
a second insulating pattern surrounding surfaces of the second connecting line excluding a surface that contacts the first connecting layer and the second source/drain structure.

11. The semiconductor device of claim 3, further comprising:
a third connecting layer extending from the first connecting layer and between the first lower source/drain and the first upper source/drain.

12. The semiconductor device of claim 11, wherein a bottom surface of the first upper source/drain contacts a top surface of the third connecting layer; and
wherein a top surface of the second lower source/drain contacts a bottom surface of the second connecting layer.

13. The semiconductor device of claim 11, wherein a top surface of the first lower source/drain contacts a bottom surface of the third connecting layer; and
wherein a bottom surface of the second upper source/drain contacts a top surface of the second connecting layer.

14. A semiconductor device, comprising:
a substrate;
a plurality of transistor stacks on the substrate; and
a plurality of source/drain structures respectively between the plurality of transistor stacks,
wherein each transistor stack of the plurality of transistor stacks comprises:
a lower transistor on the substrate, the lower transistor comprising a lower channel layer and a lower gate structure surrounding the lower channel layer; and
an upper transistor on the lower transistor, the upper transistor comprising an upper channel layer and an upper gate structure surrounding the upper channel layer,
wherein each source/drain structure of the plurality of source/drain structures comprises:
a lower source/drain between lower transistors of respective transistor stacks; and
an upper source/drain between upper transistors of respective transistor stacks,
wherein a first source/drain structure of the plurality of source/drain structures, a first transistor stack of the plurality of transistor stacks, a second source/drain structure of the plurality of source/drain structures, a second transistor stack of the plurality of transistor stacks, and a third source/drain structure of the plurality of source/drain structures are arranged in sequential order in a first direction, and
wherein the first source/drain structure and the third source/drain structure are connected via a first connecting layer in the first transistor stack, a second connecting layer in the second source/drain structure, a fourth connecting layer in the second transistor stack, and a fifth connecting layer in the third source/drain structure.

15. The semiconductor device of claim 14, wherein the first connecting layer is between a first lower channel layer and a first upper channel layer of the first transistor stack,
wherein the second connecting layer is between a second lower source/drain and a second upper source/drain of the second source/drain structure,
wherein the fourth connecting layer is between a second lower channel layer and a second upper channel layer of the second transistor stack, and
wherein the fifth connecting layer is between a third lower source/drain and a third upper source/drain of the third source/drain structure.

16. A method of manufacturing a semiconductor device, the method comprising:
forming a plurality of dummy gate structures surrounding a lower channel layer and an upper channel layer;
forming a lower source/drain between lower channel layers spaced apart from each other and that are surrounded by at least one dummy gate structure of the plurality of dummy gate structures;
forming an upper source/drain between upper channel layers spaced apart from each other and that are surrounded by at least one dummy gate structure of the plurality of dummy gate structures; and
forming a connecting layer passing between a first lower channel layer among the lower channel layers that are surrounded by at least one dummy gate structure of the plurality of dummy gate structures and a first upper channel layer of the upper channel layers that are surrounded by at least one dummy gate structure of the plurality of dummy gate structures,
wherein the lower source/drain and the upper source/drain spaced apart from at least one first dummy gate structure are connected via the connecting layer.

17. The method of claim 16, wherein the forming of the upper source/drain comprises:
forming a first upper source/drain on a first side of the at least one first dummy gate structure and extending to contact a side surface of the connecting layer; and
forming a second upper source/drain on a second side of the at least one first dummy gate structure and on the connecting layer.

18. The method of claim 17, further comprising, prior to the forming of the connecting layer:
removing the plurality of dummy gate structures; and
forming a plurality of lower gate structures surrounding at least one of the lower channel layers.

19. The method of claim 18, wherein the forming of the connecting layer comprises:
forming a connecting line; and
forming an insulating pattern,
wherein a side surface of the connecting line contacts a side surface of the first upper source/drain,
wherein a bottom surface of the connecting line contacts a top surface of a second lower source/drain, and
wherein the insulating pattern surrounds surfaces of the connecting line excluding a surface that contacts the first upper source/drain and the second lower source/drain.

20. The method of claim 19, further comprising, after the forming of the connecting layer, forming a plurality of upper gate structures surrounding the upper channel layer.
